(19) United States
(12) Patent Application Publication
(10) Pub. No.: US 2024/0023446 A1
(43) Pub. Date: Jan. 18, 2024

(54) Acoustic Resonator and Method of Forming the Same

(71) Applicant: AGENCY FOR SCIENCE, TECHNOLOGY AND RESEARCH, Singapore (SG)

(72) Inventors: Yao ZHU, Singapore (SG); Chen LIU, Singapore (SG); Nan WANG, Singapore (SG)

(73) Assignee: AGENCY FOR SCIENCE, TECHNOLOGY AND RESEARCH, Singapore (SG)

(21) Appl. No.: 18/258,347

(22) PCT Filed: Feb. 3, 2021
(86) PCT No.: PCT/SG2021/050058

§ 371 Date: Jun. 20, 2023

(51) Int. Cl. H10N 30/067; H10N 30/87; H03H 9/17; H10N 30/07; H03H 3/02

(52) U.S. Cl. CPC H10N 30/067; H10N 30/871; H03H 9/171; H10N 30/07; H03H 3/02; H03H 2009/02299

(57) ABSTRACT

Various embodiments may relate to an acoustic resonator. The acoustic resonator may include a piezoelectric layer. The acoustic resonator may also include a first electrode in contact with a first surface of the piezoelectric layer. The acoustic resonator may further include a plurality of dielectric structures in contact with the first surface of the piezoelectric layer. The acoustic resonator may additionally include a second electrode in contact with a second surface of the piezoelectric layer opposite the first surface. The first electrode may include a plurality of electrode structures. A dielectric structure of the plurality of dielectric structures may be in contact with a pair of neighboring electrode structures of the plurality of electrode structures.

### TECHNICAL FIELD

Various embodiments of this disclosure may relate to an acoustic resonator. Various embodiments of this disclosure may relate to a method of forming an acoustic resonator.

### BACKGROUND

With the development of 5G communication technology, the demand for radio frequency (RF) filters with high working frequency and high bandwidth is increasing dramatically. While surface acoustic wave (SAW) based filters are dominating the low and mid band, bulk acoustic wave (BAW) filters are the mainstream technology in high band over 2 GHz. However, due to the film-stack dependent resonant frequency of BAW, the film stack has to be modified by either trimming or adding an additional loading layer in order to fabricate BAW resonators with different frequencies on the same wafer, which increases the fabrication complexity and cost. In order to overcome this challenge, various micro-acoustic resonator designs have been proposed to adjust the resonator operating frequency by electrode patterning, such as the Lamb mode resonator, the laterally coupled thickness (LCAT) mode resonator, the two-dimensional-mode resonator (2DMR), the cross-sectional-Lamé-mode resonator (CLMR) and the recent laterally coupled bulk acoustic resonators (CBAR). Other than operating frequency, the effective coupling coefficient (k²_{eff}) of a resonator is another important parameter which limits the highest achievable bandwidth of the filter constructed by such resonators. An universal challenge for these emerging resonators relates to how to achieve BAW resonators comparable effective coupling coefficient (k²_{eff}) and maintain it across the designed frequency range, though the CBAR shows a higher achieved k²_{eff} compared to other emerging resonators so far.

### SUMMARY

Various embodiments may relate to an acoustic resonator. The acoustic resonator may include a piezoelectric layer. The acoustic resonator may also include a first electrode in contact with a first surface of the piezoelectric layer. The acoustic resonator may further include a plurality of dielectric structures in contact with the first surface of the piezoelectric layer. The acoustic resonator may additionally include a second electrode in contact with a second surface of the piezoelectric layer opposite the first surface. The first electrode may include a plurality of electrode structures. A dielectric structure of the plurality of dielectric structures may be in contact with a pair of neighboring electrode structures of the plurality of electrode structures.

Various embodiments may relate to a method of forming an acoustic resonator. The method may include forming a first electrode in contact with a first surface of a piezoelectric layer. The method may also include forming a plurality of dielectric structures in contact with the first surface of the piezoelectric layer. The method may additionally include forming a second electrode in contact with a second surface of the piezoelectric layer opposite the first surface. The first electrode may include a plurality of electrode structures. A dielectric structure of the plurality of dielectric structures may be in contact with a pair of neighboring electrode structures of the plurality of electrode structures.

### BRIEF DESCRIPTION OF THE DRAWINGS

In the drawings, like reference characters generally refer to the same parts throughout the different views. The drawings are not necessarily drawn to scale, emphasis instead generally being placed upon illustrating the principles of various embodiments. In the following description, various embodiments of the invention are described with reference to the following drawings.

FIG. 1A shows schematics of (above) a cross-sectional view of a Lamb wave mode resonator with dielectric material; and (below) a top view of the Lamb wave mode resonator with the dielectric material.

FIG. 1B shows schematics of (above) a cross-sectional view of a bulk acoustic wave (BAW) mode resonator with dielectric material as loading layer; and (below) a top view of the bulk acoustic wave (BAW) mode resonator with the dielectric material as loading layer.

FIG. 1C shows a plot of frequency (in gigahertz or GHz)/effective coupling coefficient as a function of dielectric thickness (in micrometers or μm) illustrating the simulation results of a Lamb wave mode resonator.

FIG. 1D shows a plot of effective coupling coefficient as a function of dielectric thickness (in micrometers or μm) illustrating the simulation results of a bulk acoustic wave (BAW) mode resonator.

FIG. 2 is a general illustration of an acoustic resonator according to various embodiments.

FIG. 3 is a general illustration of a method of forming an acoustic resonator according to various embodiments.

FIG. 4 includes (a) a schematic showing a cross-sectional view of a conventional bulk acoustic wave (BAW) resonator; (b) a schematic showing a cross-sectional view of a conventional coupled bulk acoustic resonator (CBAR); and (c) a schematic showing a top view of the conventional coupled bulk acoustic resonator (CBAR).

FIG. 5A is a plot of frequency (in gigahertz or GHz)/effective coupling coefficient as a function of pitch (in micrometers or μm) illustrating the dependence of resonant frequent and effective coupling coefficient of a coupled bulk acoustic resonator (CBAR) on the electrode pitch. The electrode width may be equal to the space (elecwid=spac).

FIG. 5B is a plot of frequency (in gigahertz or GHz)/effective coupling coefficient as a function of electrode width (elecwid, in micrometers or μm) illustrating the performance of a coupled bulk acoustic resonator (CBAR) in which the ratio of the electrode width (elecwid) and the space (spac) is constant at 2:1.

FIG. 5C is a plot of frequency (in gigahertz or GHz)/effective coupling coefficient as a function of electrode width (elecwid, in micrometers or μm) illustrating the performance of a coupled bulk acoustic resonator (CBAR) with varying electrode width (elecwid) and constant space (spac=0.25 μm).

FIG. 5D is a plot of frequency (in gigahertz or GHz)/effective coupling coefficient as a function of spacing (spac, in micrometers or μm) illustrating the performance of a coupled bulk acoustic resonator (CBAR) with varying spacings (spac) and constant electrode width (elecwid).

FIG. 6A shows a schematic of a cross-sectional view of a coupled bulk acoustic resonator (CBAR) with dielectric material filling the spaces according to various embodiments.

FIG. 6B shows a schematic of a cross-sectional view of the coupled bulk acoustic resonator (CBAR) with dielectric material filling the spaces and with voltages applied according to various embodiments.

FIG. 7A is a plot of frequency (in gigahertz or GHz) as a function of pitch (in micrometers or μm) showing the simulated resonant frequencies of coupled bulk acoustic resonators with different thicknesses of dielectric (aluminum oxide Al₂O₃) filling according to various embodiments and of a coupled bulk acoustic resonator with no dielectric filling.

FIG. 7B is a plot of effective coupling coefficient as a function of pitch (in micrometers or μm) showing the simulated effective coupling coefficients (k²_{eff}) of coupled bulk acoustic resonators with different thicknesses of dielectric (aluminum oxide Al₂O₃) filling according to various embodiments and of a coupled bulk acoustic resonator with no dielectric filling.

FIG. 7C is a plot of frequency (in gigahertz or GHz) as a function of electrode width (elecwid, in micrometers or μm) with constant space (spac=0.25 μm) showing the simulated resonant frequencies of coupled bulk acoustic resonators with different thicknesses of dielectric (aluminum oxide Al₂^{O}₃) filling according to various embodiments and of a coupled bulk acoustic resonator with no dielectric filling.

FIG. 7D is a plot of effective coupling coefficient as a function of electrode width (elecwid, in micrometers or μm) with constant space (spac=0.25 μm) showing the simulated effective coupling coefficient of coupled bulk acoustic resonators with different thicknesses of dielectric (aluminum oxide Al₂O₃) filling according to various embodiments and of a coupled bulk acoustic resonator with no dielectric filling.

FIG. 8A is a plot of effective coupling coefficient as a function of Young's modulus (in Pascals or Pa) highlighting the dependence of the effective coupling coefficient (k²_{eff}) on the Young's modulus of dielectric filling in coupled bulk acoustic resonators with different thicknesses of the dielectric filling according to various embodiments.

FIG. 8B is a plot of effective coupling coefficient as a function of density (in kilograms per cubic meters or kg/m³) highlighting the dependence of the effective coupling coefficient (k²_{eff}) on the density of dielectric filling in coupled bulk acoustic resonators with different thicknesses of the dielectric filling according to various embodiments.

FIG. 8C is a plot of effective coupling coefficient as a function of Poisson ratio highlighting the dependence of the effective coupling coefficient (k²_{eff}) on the Poisson ratio of dielectric filling in coupled bulk acoustic resonators with different thicknesses of the dielectric filling according to various embodiments.

FIG. 9A shows a schematic of a cross-sectional view of a coupled bulk acoustic resonator (CBAR) with dielectric structures on the top surfaces of the electrode structures and on the piezoelectric layer not covered by the electrode structures, but not on the sidewalls of the electrode structures according to various embodiments.

FIG. 9B shows a schematic of a cross-sectional view of a coupled bulk acoustic resonator (CBAR) in which the dielectric structure extends from between the pair of neighboring electrode structures (i.e. on the piezoelectric layer not covered by the electrode structures) along the opposite facing sidewalls to over the electrode structures according to various embodiments.

FIG. 10A is a plot of frequency (in gigahertz or GHz)/effective coupling coefficient as a function of filling thickness (in micrometers or μm) showing the performance of a coupled bulk acoustic resonator (CBAR) as illustrated by FIG. 9.B according to various embodiments.

FIG. 10B is a plot of frequency (in gigahertz or GHz) as a function of pitch (in micrometers or μm) comparing a coupled bulk acoustic resonator (CBAR) with dielectric filling on the side walls according to various embodiments with a coupled bulk acoustic resonator (CBAR) with no dielectric filling.

FIG. 10C is a plot of effective coupling coefficient as a function of pitch (in micrometers or μm) comparing a coupled bulk acoustic resonator (CBAR) with dielectric filling on the side walls according to various embodiments with a coupled bulk acoustic resonator (CBAR) with no dielectric filling.

FIG. 11A is a plot of frequency (in gigahertz or GHz) as a function of pitch (in micrometers or μm) showing the simulated resonant frequencies of coupled bulk acoustic resonators (CBAR) with different thicknesses of dielectric fillings on the top electrode (i.e. without dielectric filling along the side walls) according to various embodiments as well as a coupled bulk acoustic resonator (CBAR) without any dielectric filling.

FIG. 11B is a plot of effective coupling coefficient as a function of pitch (in micrometers or μm) showing the simulated effective coupling coefficients of coupled bulk acoustic resonators (CBAR) with different thicknesses of dielectric fillings on the top electrode (i.e. without dielectric filling along the side walls) according to various embodiments as well as a coupled bulk acoustic resonator (CBAR) without any dielectric filling.

FIG. 12A is a schematic showing a cross-sectional view of a coupled bulk acoustic resonator (CBAR) according to various embodiments.

FIG. 12B is a plot of frequency (in gigahertz or GHz) as a function of pitch (in micrometers or μm) showing the resonant frequencies of the coupled bulk acoustic resonator (CBAR) shown in FIG. 12A with different dielectric thicknesses according to various embodiments as well as a coupled bulk acoustic resonator (CBAR) with no dielectric filling.

FIG. 12C is a plot of effective coupling coefficient as a function of pitch (in micrometers or μm) showing the effective coupling coefficient of the coupled bulk acoustic resonator (CBAR) shown in FIG. 12A with different dielectric thicknesses according to various embodiments as well as a coupled bulk acoustic resonator (CBAR) with no dielectric filling.

FIG. 13A is a schematic showing a cross-sectional view of a coupled bulk acoustic resonator (CBAR) according to various embodiments.

FIG. 13B is a schematic showing a top view of the coupled bulk acoustic resonator (CBAR) shown in FIG. 13A according to various embodiments.

FIG. 14 is a schematic showing a top view of a coupled bulk acoustic resonator (CBAR) according to various embodiments.

FIG. 15A is a schematic showing a cross-sectional view of a coupled bulk acoustic resonator (CBAR) according to various embodiments.

FIG. 15B is a schematic showing a top view of the coupled bulk acoustic resonator (CBAR) shown in FIG. 15A according to various embodiments.

FIG. 16A is a schematic showing a top view of a coupled bulk acoustic resonator (CBAR) according to various embodiments.

FIG. 16B is a schematic showing a top view of a coupled bulk acoustic resonator (CBAR) according to various other embodiments.

FIG. 16C is a schematic showing a top view of a coupled bulk acoustic resonator (CBAR) according to various other embodiments.

FIG. 17A is a schematic showing a cross-sectional view of a coupled bulk acoustic resonator (CBAR) according to various embodiments.

FIG. 17B is a schematic showing a top view of the coupled bulk acoustic resonator (CBAR) shown in FIG. 17A according to various embodiments.

FIG. 18A is a schematic showing a cross-sectional view of a coupled bulk acoustic resonator (CBAR) according to various embodiments.

FIG. 18B is a schematic showing a top view of the coupled bulk acoustic resonator (CBAR) shown in FIG. 18A according to various embodiments.

### DESCRIPTION

The following detailed description refers to the accompanying drawings that show, by way of illustration, specific details and embodiments in which the invention may be practiced. These embodiments are described in sufficient detail to enable those skilled in the art to practice the invention. Other embodiments may be utilized and structural, logical, and electrical changes may be made without departing from the scope of the invention. The various embodiments are not necessarily mutually exclusive, as some embodiments can be combined with one or more other embodiments to form new embodiments.

Embodiments described in the context of one of the methods or resonators are analogously valid for the other methods or resonators. Similarly, embodiments described in the context of a method are analogously valid for a resonator, and vice versa.

Features that are described in the context of an embodiment may correspondingly be applicable to the same or similar features in the other embodiments. Features that are described in the context of an embodiment may correspondingly be applicable to the other embodiments, even if not explicitly described in these other embodiments. Furthermore, additions and/or combinations and/or alternatives as described for a feature in the context of an embodiment may correspondingly be applicable to the same or similar feature in the other embodiments.

The resonator as described herein may be operable in various orientations, and thus it should be understood that the terms “top”, “bottom”, etc., when used in the following description are used for convenience and to aid understanding of relative positions or directions, and not intended to limit the orientation of the resonator.

In the context of various embodiments, the articles “a”, “an” and “the” as used with regard to a feature or element include a reference to one or more of the features or elements.

In the context of various embodiments, the term “about” or “approximately” as applied to a numeric value encompasses the exact value and a reasonable variance.

As used herein, the term “and/or” includes any and all combinations of one or more of the associated listed items.

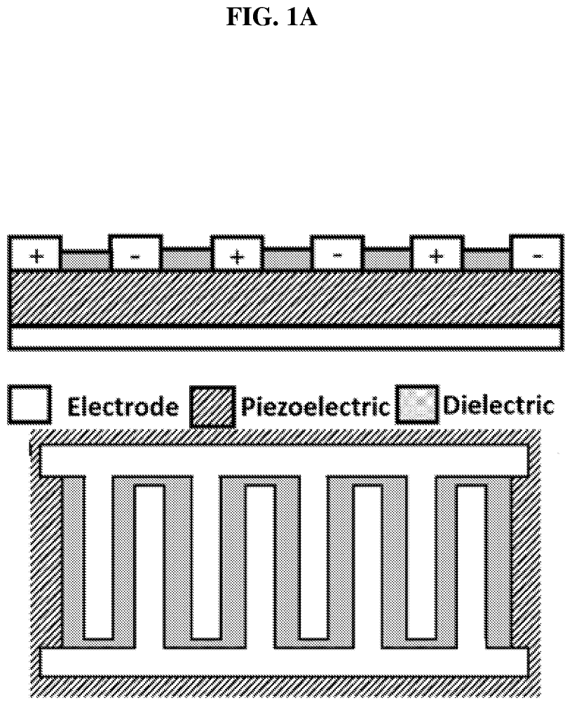

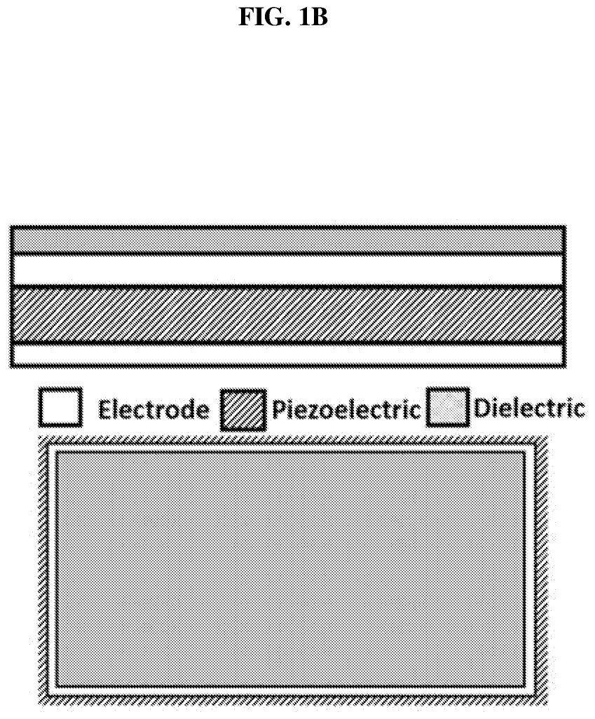

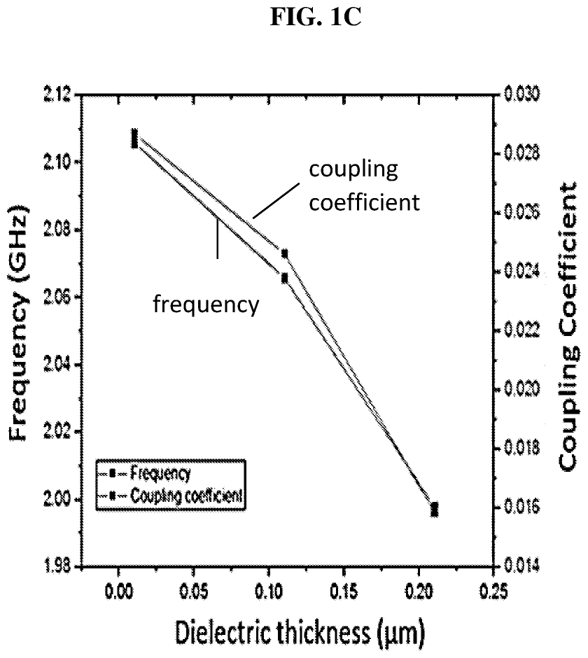

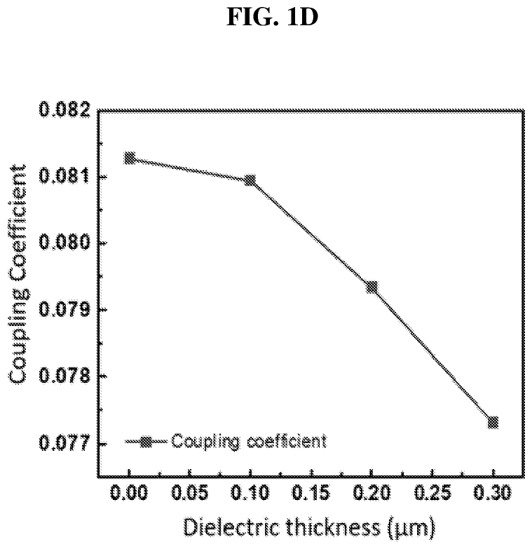

Dielectric material has been used in radio frequency micro-electromechanical system (RFMEMS) resonators previously mainly for temperature compensation. However, the addition of dielectric materials is usually accompanied with the reduction of the k²_{eff} of the resonators, as confirmed by literature and in simulations. There are references that reported that k²_{eff} dramatically reduces for bulk acoustic wave (BAW) and surface acoustic wave (SAW) resonators. FIG. 1A shows schematics of (above) a cross-sectional view of a Lamb wave mode resonator with dielectric material; and (below) a top view of the Lamb wave mode resonator with the dielectric material. FIG. 1B shows schematics of (above) a cross-sectional view of a bulk acoustic wave (BAW) mode resonator with dielectric material as loading layer; and (below) a top view of the bulk acoustic wave (BAW) mode resonator with the dielectric material as loading layer. FIG. 1C shows a plot of frequency (in gigahertz or GHz)/effective coupling coefficient as a function of dielectric thickness (in micrometers or μm) illustrating the simulation results of a Lamb wave mode resonator. FIG. 1D shows a plot of effective coupling coefficient as a function of dielectric thickness (in micrometers or μm) illustrating the simulation results of a bulk acoustic wave (BAW) mode resonator.

Based on the simulation results shown in FIGS. 1C-D, for resonators with plate or alternate interdigitated (IDT) top electrode, the effective coupling coefficient (k²_{eff}) decreases with increase of the thickness of the dielectric layer. In contrast, in various embodiments described herein, the k²_{eff} improves with the addition of dielectric material. Various embodiments may provide unexpected improvements over existing resonators.

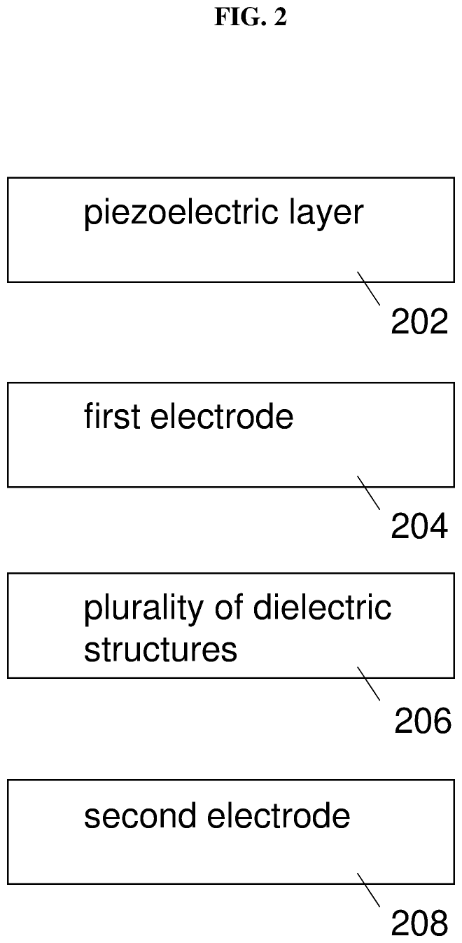

FIG. 2 is a general illustration of an acoustic resonator according to various embodiments. The acoustic resonator may include a piezoelectric layer 202. The acoustic resonator may also include a first electrode 204 in contact with a first surface of the piezoelectric layer 202. The acoustic resonator may further include a plurality of dielectric structures 206 in contact with the first surface of the piezoelectric layer 202. The acoustic resonator may additionally include a second electrode 208 in contact with a second surface of the piezoelectric layer 202 opposite the first surface. The first electrode 204 may include a plurality of electrode structures. A dielectric structure of the plurality of dielectric structures 206 may be in contact with a pair of neighboring electrode structures of the plurality of electrode structures.

In other words, the acoustic resonator may include a piezoelectric layer 202, a first electrode 204 including a plurality of electrode structures as well as a plurality of dielectric structures 206 on one side of the piezoelectric layer 202, and a second electrode 208 on an opposing side of the piezoelectric layer 202. The first electrode may include a plurality of electrode structures. A dielectric structure of the plurality of dielectric structures may be in contact with a pair of neighboring electrode structures of the plurality of electrode structures.

In the current context, a pair of neighboring electrode structures may refer to a particular electrode structure and one of the remaining electrode structures closest to the particular electrode structure.

In various embodiments, the dielectric structure may adjoin the neighboring pair of electrodes. In various embodiments, the resonant frequency may be adjustable by lithographic patterning. Various embodiments may enhance the effective coupling coefficient.

In various embodiments, each dielectric structure of the plurality of dielectric structures may be in contact with a pair of neighboring electrode structures. Each dielectric structure may adjoin a pair of neighboring electrode structures.

In various embodiments, a pitch between one pair of neighboring electrode structures of the plurality of electrode structures and a pitch between another pair of neighboring electrode structures of the plurality of electrode structures may be equal.

In various other embodiments, a pitch between one pair of neighboring electrode structures of the plurality of electrode structures may not be equal to a pitch between another pair of neighboring electrode structures of the plurality of electrode structures.

In various embodiments, the first electrode 204 may include an electrode bar. The plurality of electrode structures may extend from the electrode bar. The electrode bar may be the only electrode bar of the first electrode 204.

In other embodiments, the first electrode 204 may include an electrode bar and also a further electrode bar such that the plurality of electrode structures extends from the electrode bar to the further electrode bar. In yet various other embodiments, the first electrode 204 may further include one or more additional electrode bars across the plurality of electrode structures such that the first electrode 204 is a mesh. In other words, the first electrode 204 may include additional electrode bars such that the electrode bar, the further electrode bar, the plurality of electrode structures, and any one or more additional electrode bars form a mesh. The mesh may include a plurality of cavities defined by the electrode bar, the further electrode bar, the plurality of electrode structures, and any one or more additional electrode bars.

The electrode structures may alternatively be referred to as “electrode fingers”. In various embodiments, the plurality of electrode structures may be parallel to one another. In various other embodiments, the plurality of electrode structures may not be parallel to one another. In various embodiments, the plurality of electrode structures may be elongate structures. In various embodiments, the plurality of electrode structures may be straight. In various other embodiments, the plurality of electrode structures may not be straight and/or may be of any suitable shapes.

In various embodiments, the cavities may be square or rectangular (i.e. having a square or rectangular perimeter as defined by the electrode bars and the electrode structures). In various other embodiments, the cavities may be of any suitable shape, e.g. triangular, hexagonal, circular etc.

In various embodiments, the dielectric structure may cover opposite facing sidewalls of the pair of the neighboring electrode structures. In various embodiments, the dielectric structure may further extend from between the pair of neighboring electrode structures along the opposite facing sidewalls to over the pair of neighboring electrode structures. In yet various other embodiments, in addition to the dielectric structures in contact with the piezoelectric layer 202, the resonator may include a further plurality of dielectric structure covering or be in contact with only a top surface of each of the pair of neighboring electrode structures. In other words, there may not be a dielectric layer covering or in contact with entire sidewalls of the electrode structures.

In various embodiments, the plurality of electrode structures may have a first thickness, and the plurality of dielectric structures may have a second thickness equal to the first thickness. In various other embodiments, the plurality of electrode structures may have a first thickness, and the plurality of dielectric structures may have a second thickness not equal to the first thickness.

In various embodiments, the plurality of electrode structures may be configured to be applied with a first voltage and the second electrode may be configured to be applied with a second voltage different from the first voltage.

In various embodiments, the second surface of the piezoelectric layer may be in contact with an entirety of a surface of the second electrode. There may be no bottom dielectric layer which is in contact with either the second surface of the piezoelectric layer or the second electrode. In various embodiments, the second electrode may be a plate electrode. In various other embodiments, the second electrode may not be a plate electrode.

In various embodiments, the plurality of dielectric structures may include any one material selected from a group consisting of aluminum oxide (Al₂O₃), silicon nitride (Si₃N₄), silicon dioxide (SiO₂), zinc oxide (ZnO), aluminum nitride (AlN), scandium aluminum nitride (ScAlN), hafnium oxide (HfO₂), titanium oxide (TiO₂), ruthenium oxide (RuO₂), hafnium silicate (HfSiO₄), zirconium oxide (ZrO₂), zirconium silicate (ZrSiO₄), tantalum oxide (Ta₂O₅), hafnium zirconium oxide (HfZrO₄).

The acoustic resonator may be a coupled bulk acoustic resonator (CBAR)

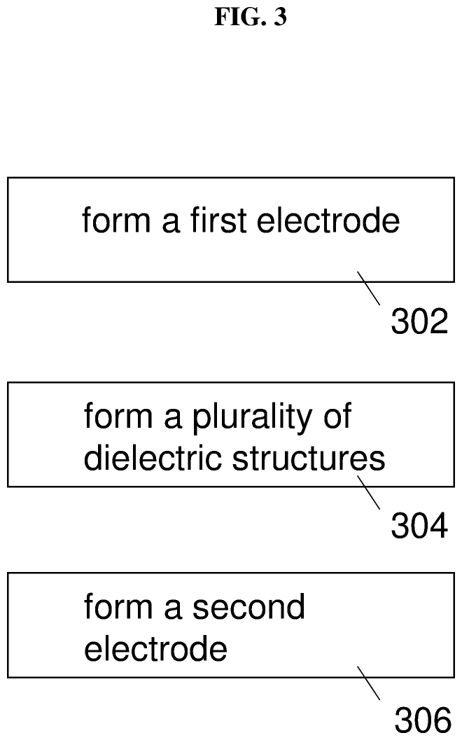

FIG. 3 is a general illustration of a method of forming an acoustic resonator according to various embodiments. The method may include, in 302, forming a first electrode in contact with a first surface of a piezoelectric layer. The method may also include, in 304, forming a plurality of dielectric structures in contact with the first surface of the piezoelectric layer. The method may additionally include, in 306, forming a second electrode in contact with a second surface of the piezoelectric layer opposite the first surface. The first electrode may include a plurality of electrode structures. A dielectric structure of the plurality of dielectric structures may be in contact with a pair of neighboring electrode structures of the plurality of electrode structures.

In other words, the method may include forming a first electrode and a plurality of dielectric structures on one surface of a piezoelectric layer, and forming a second electrode on an opposing surface of the piezoelectric layer. The first electrode may include multiple electrode structures. Each dielectric structure may adjoin two neighboring electrode structures.

In various embodiments, a pitch between one first pair of neighboring electrode structures of the plurality of electrode structures and a pitch between another pair of neighboring electrode structures of the plurality of electrode structures may be equal.

In various other embodiments, a pitch between one pair of neighboring electrode structures of the plurality of electrode structures may not be equal to a pitch between another pair of neighboring electrode structures of the plurality of electrode structures.

In various embodiments, the first electrode may include an electrode bar, and a plurality of electrode structures extending from the electrode bar. The electrode bar may be the only electrode bar of the first electrode.

In various other embodiments, the first electrode may include an electrode bar and also a further electrode bar such that the plurality of electrode structures extends from the electrode bar to the further electrode bar. In yet various other embodiments, the first electrode may further include one or more additional electrode bars across the plurality of electrode structures such that the first electrode is a mesh.

In various embodiments, the dielectric structure may cover opposite facing sidewalls of the pair of the neighboring electrode structures. In various embodiments, the dielectric structure may further extend from between the pair of neighboring electrode structures along the opposite facing sidewalls to over the pair of neighboring electrode structures. In yet various other embodiments, in addition to the dielectric structures in contact with the piezoelectric layer, the resonator may include a further plurality of dielectric structure covering or be in contact with only a top surface of each of the pair of neighboring electrode structures. In other words, there may not be a dielectric layer covering or in contact with entire sidewalls of the electrode structures.

In various embodiments, the plurality of electrode structures may have a first thickness, and the plurality of dielectric structures may have a second thickness equal to the first thickness. In various other embodiments, the plurality of electrode structures may have a first thickness, and the plurality of dielectric structures may have a second thickness not equal to the first thickness.

In various embodiments, the plurality of electrode structures may be configured to be applied with a first voltage and the second electrode may be configured to be applied with a second voltage different from the first voltage.

In various embodiments, the second surface of the piezoelectric layer may be in contact with an entirety of a surface of the second electrode. There may be no bottom dielectric layer which is in contact with either the second surface of the piezoelectric layer or the second electrode.

In various embodiments, the plurality of dielectric structures may include any one material selected from a group consisting of aluminum oxide (Al₂O₃), silicon nitride (Si₃N₄), silicon dioxide (SiO₂), zinc oxide (ZnO), aluminum nitride (AlN), scandium aluminum nitride (ScAlN), hafnium oxide (HfO₂), titanium oxide (TiO₂), ruthenium oxide (RuO₂), hafnium silicate (HfSiO₄), zirconium oxide (ZrO₂), zirconium silicate (ZrSiO₄), tantalum oxide (Ta₂O₅), hafnium zirconium oxide (HfZrO₄).

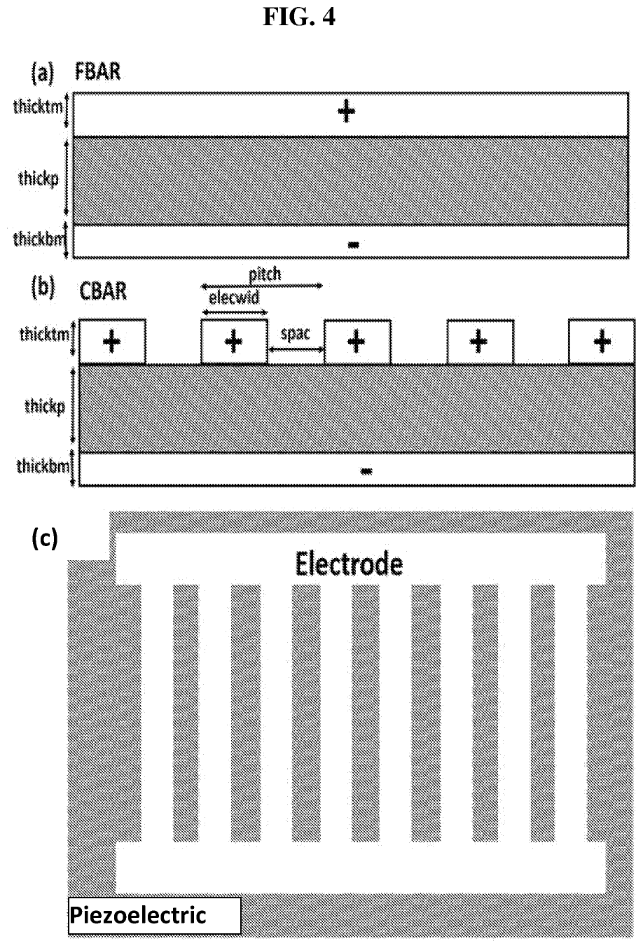

FIG. 4 includes (a) a schematic showing a cross-sectional view of a conventional bulk acoustic wave (BAW) resonator; (b) a schematic showing a cross-sectional view of a conventional coupled bulk acoustic resonator (CBAR); and (c) a schematic showing a top view of the conventional coupled bulk acoustic resonator (CBAR).

The cross-section of the classic CBAR structure as shown in FIG. 4(b) has a piezoelectric layer sandwiched between top and bottom electrode layers. Instead of electrode plates for conventional BAW structure as shown in FIG. 4(a), the top electrode layer is etched and patterned as comb fingers, while the bottom electrode is a plate. Unlike the Lamb wave mode resonators (shown in FIG. 1A) whose adjacent electrode fingers are excited by electrical signals with opposite polarities, in the CBAR, all top electrode fingers are electrically connected by a bus bar as illustrated in FIG. 4(c). In various embodiments, the top electrode fingers and the bus bar may be at the same layer. In various other embodiments, the top electrode fingers and the bus bar may be at different layers, and the top electrode fingers may be electrically connected to the bus bar via intermediate connectors such as through vias, or via adjacent layers contact. In yet various other embodiments, the bus bar or any suitable electrical connecting structure may be outside the resonator area, and the top electrode fingers may be electrically connected to the bus bar or the suitable electrical connecting structure outside the resonator area. Signals with opposite polarities are applied between the top and bottom electrodes as shown in FIG. 4(b). With this configuration, like other BAW resonators, the thickness vibration modes can be exited in the piezoelectric layer. Meanwhile, due to the finger configuration of the top electrode, the lateral propagation of the thickness mode causes a specific distribution of vertical displacement under each electrode finger. As such, the resonance mode of the CBAR may be dependent on the coupling of the thickness mode and the lateral mode. In this way the resonance frequency of the CBAR may be determined not only by the thickness configuration of the electrode/piezoelectric/electrode stack, but also by finger shape and dimensions of the top electrode.

The structural parameters of the CBAR are as shown in FIG. 4(b). To quantify the performance of the resonators, 2-dimentional (2D) finite electrode analysis (FEA) using COMSOL is performed to obtain the impedance-frequency response plots of resonators with various finger widths (elecwid) and spaces (spac). Pitch is defined as the length of a periodic pattern (elecwid+spac). In the simulation, the electrode material is molybdenum (Mo) and the piezoelectric material is aluminum nitride (AlN). To analyze the impact of the finger configuration, the stack thickness is fixed to 0.26 μm (top electrode)/1 μm (piezoelectric layer)/0.2 μm (bottom electrode). The effective coupling coefficient (k²_{eff}) of the resonator is calculated using equation (1), where fₛ is the series resonant frequency when the resonator has the minimum impedance (Rₛ), and fₚ is the parallel resonant frequency when the resonator reaches its largest impedance (Rₚ).

$${k}_{eff}^{2} = \frac{π}{2} \frac{{f}_{s}}{{f}_{p}} \frac{1}{tan ( \frac{π {f}_{s}}{2 {f}_{p}} )} \qquad ( 1 )$$

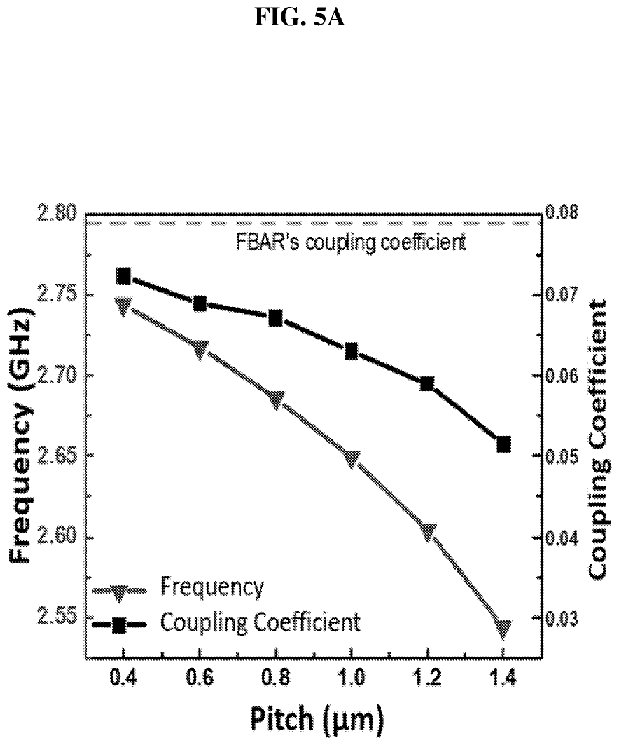

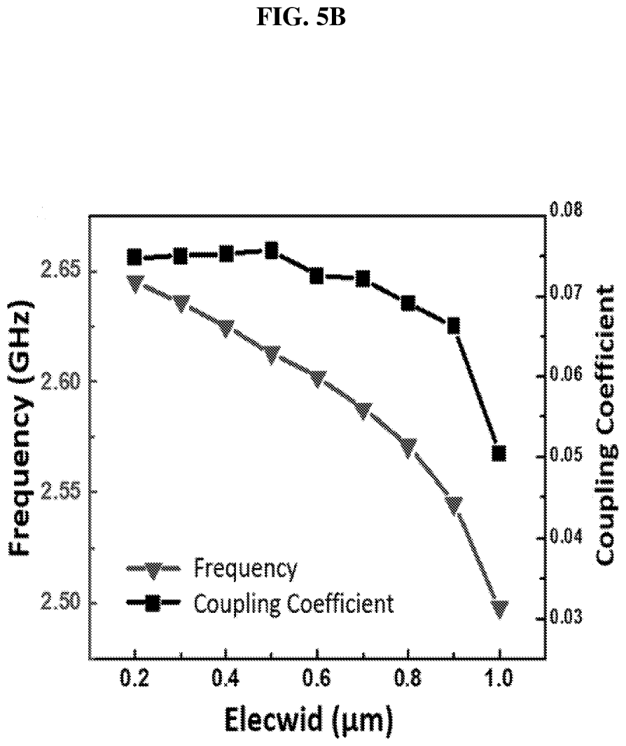

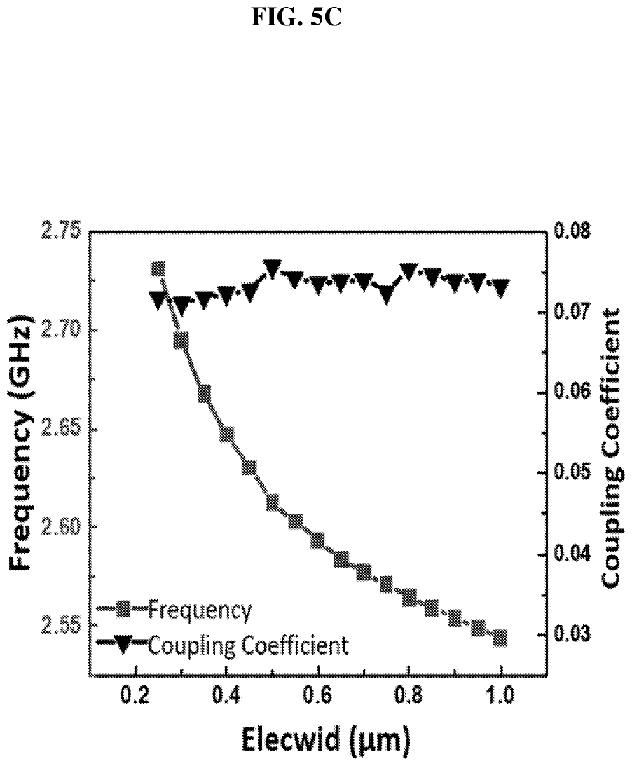

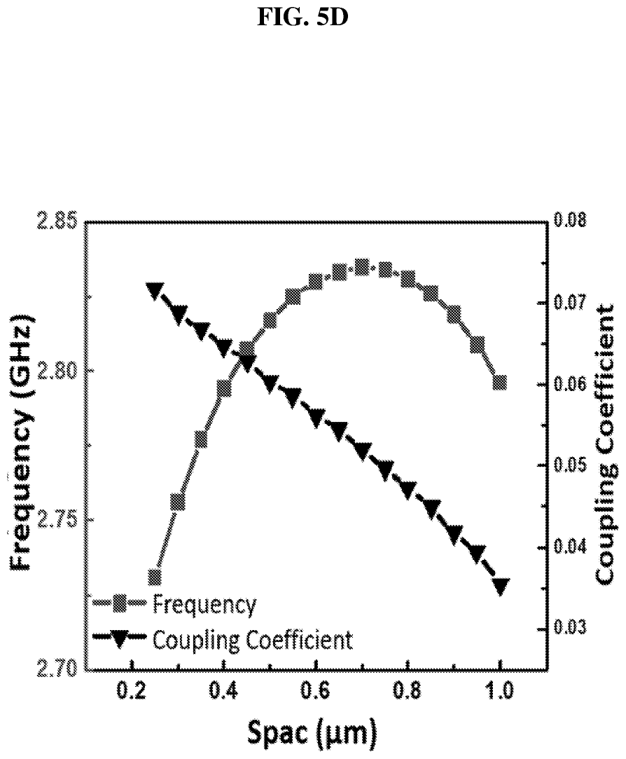

To figure out the most critical structural parameter for the resonant frequency and k²_{eff}, various configurations of the patterned top electrode fingers and the simulation results of CBAR resonators are shown in FIGS. 5A-D.

FIG. 5A is a plot of frequency (in gigahertz or GHz)/effective coupling coefficient as a function of pitch (in micrometers or μm) illustrating the dependence of resonant frequent and effective coupling coefficient of a coupled bulk acoustic resonator (CBAR) on the electrode pitch. The electrode width may be equal to the space (elecwid=spac). FIG. 5B is a plot of frequency (in gigahertz or GHz)/effective coupling coefficient as a function of electrode width (elecwid, in micrometers or μm) illustrating the performance of a coupled bulk acoustic resonator (CBAR) in which the ratio of the electrode width (elecwid) and the space (spac) is constant at 2:1. FIG. 5C is a plot of frequency (in gigahertz or GHz)/effective coupling coefficient as a function of electrode width (elecwid, in micrometers or μm) illustrating the performance of a coupled bulk acoustic resonator (CBAR) with varying electrode width (elecwid) and constant space (spac=0.25 μm). FIG. 5D is a plot of frequency (in gigahertz or GHz)/effective coupling coefficient as a function of spacing (spac, in micrometers or μm) illustrating the performance of a coupled bulk acoustic resonator (CBAR) with varying spacings (spac) and constant electrode width (elecwid).

As shown in the FIG. 5A, the resonant frequency of a CBAR can be tuned from 2.75 GHz to 2.55 GHz with the increase of the pitch from 0.4 μm to 1.4 μm, which means both the width of the fingers and the space are increased from 0.2 μm to 0.7 μm. Along with the decrease of the resonant frequency, the k²_{eff} reduces from over 7% to around 5%. For comparison, the k²_{eff} of the BAW resonator with same stack thickness is 7.9%. Then, the impact of the electrode width and the space are studied. The results as shown in FIGS. 5B-D show that k²_{eff} drops with the increase of the electrode space, while the k²_{eff} is not very sensitive to the width of electrode fingers when the electrode space is kept at a constant small number. In order to make the resonator useful for RF bandpass filter applications, the k²_{eff} cannot be too small.

In order to further improve the k²_{eff} over the desired frequency, the CBAR structure may be modified by filling the spaces between top electrode fingers with dielectric materials such as aluminum oxide (Al₂O₃), silicon nitride (Si₃N₄), silicon dioxide (SiO₂), etc.

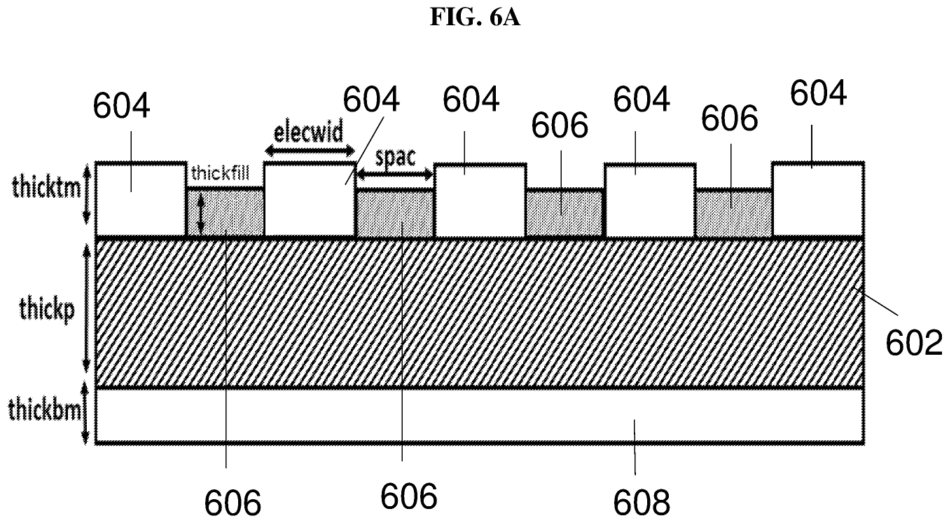

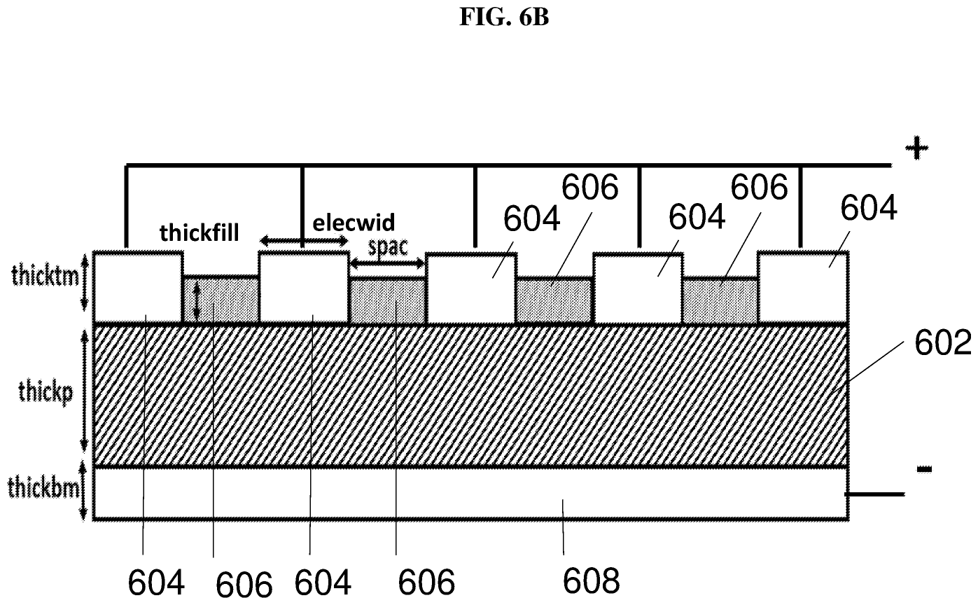

FIG. 6A shows a schematic of a cross-sectional view of a coupled bulk acoustic resonator (CBAR) with dielectric material filling the spaces according to various embodiments. FIG. 6B shows a schematic of a cross-sectional view of the coupled bulk acoustic resonator (CBAR) with dielectric material filling the spaces and with voltages applied according to various embodiments. Unlike the conventional coupled bulk acoustic resonator (CBAR), the coupled bulk acoustic resonators shown in FIGS. 6A-B may include a plurality of dielectric structures 606.

The acoustic resonator may include a piezoelectric layer 602. The acoustic resonator may also include a first electrode 604 in contact with a first surface of the piezoelectric layer 602. The acoustic resonator may further include a plurality of dielectric structures 606 in contact with the first surface of the piezoelectric layer 602. The acoustic resonator may additionally include a second electrode 608 in contact with a second surface of the piezoelectric layer 602 opposite the first surface. The first electrode 604 may include a plurality of electrode structures. A dielectric structure of the plurality of dielectric structures 606 may be in contact with a pair of neighboring electrode structures of the plurality of electrode structures. While FIG. 6B shows a positive voltage applied to the first electrode 604 and a negative voltage applied to the second electrode 608, various embodiments may require only different voltages to be applied to the first electrode 604 and to the second electrode 608. In other words, the voltages applied to the first electrode 604 and the second electrode 608 may be of the same polarity with different magnitudes.

The practical design range of the dimensions for a modified CBAR resonator may be that the thicktm<0.5×thickp, thickbm<0.5×thickp, spac<0.6×(thicktm+thickp+thickbm). In other words, the thickness (thicktm) of each first electrode layer 604 may be less than half the thickness (thickp) of the piezoelectric layer 602. The thickness (thickbm) of the second electrode 608 may also be less than half the thickness (thickp) of the piezoelectric layer 602. The spacing between neighboring electrodes or the width of each dielectric structure may be less than 0.6 times the sum of the thickness (thicktm) of the first electrode layer 604, the thickness (thickp) of the piezoelectric layer 602, and the thickness (thickbm) of the second electrode 608.

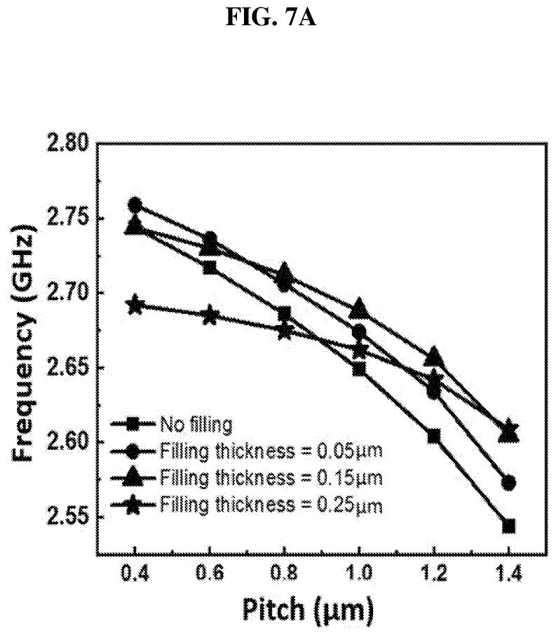

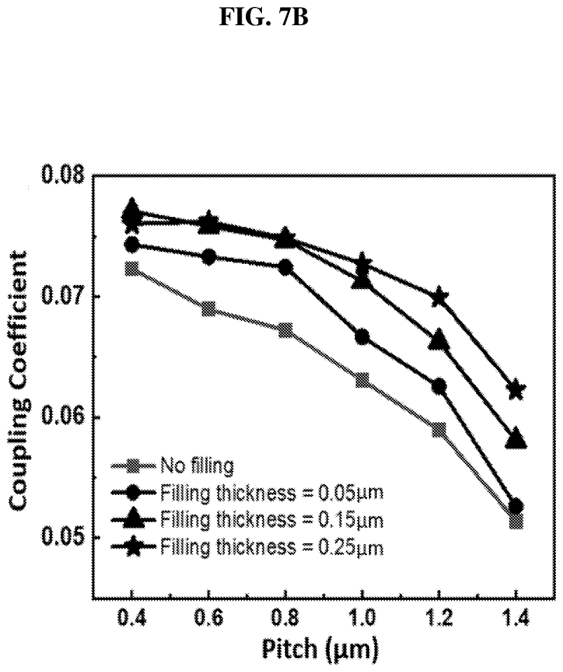

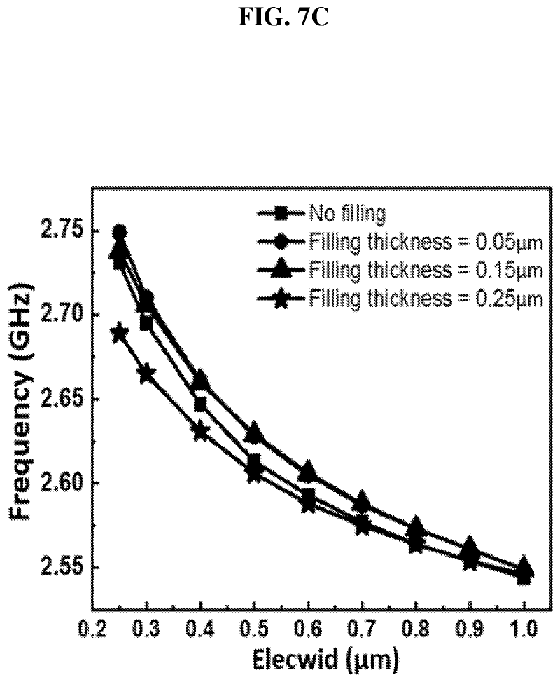

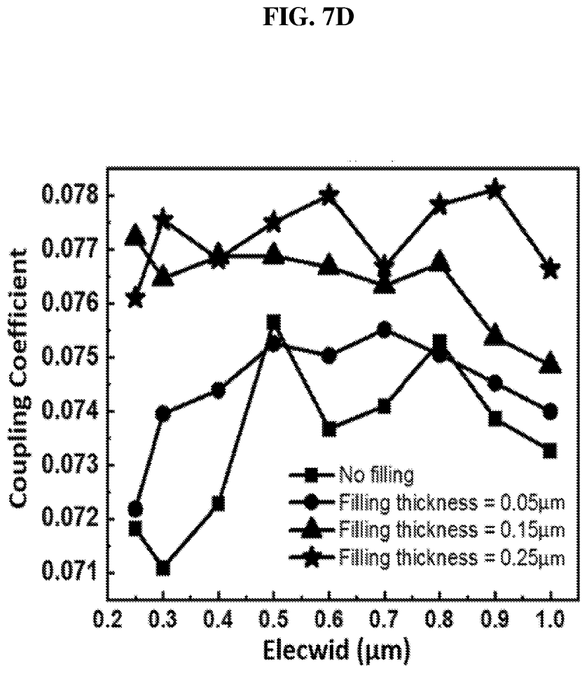

In order to evaluate the quantitative effect of the dielectric filling, the modified CBAR structure as shown in FIG. 6A is simulated, with the baseline stack thickness of 0.26 μm (top Mo electrode)/1 μm (piezoelectric AlN layer)/0.2 μm (bottom Mo electrode). The simulation results of the modified CBAR with Al₂O₃ filling are shown in FIGS. 7A-D.

FIG. 7A is a plot of frequency (in gigahertz or GHz) as a function of pitch (in micrometers or μm) showing the simulated resonant frequencies of coupled bulk acoustic resonators with different thicknesses of dielectric (aluminum oxide Al₂O₃) filling according to various embodiments and of a coupled bulk acoustic resonator with no dielectric filling. FIG. 7B is a plot of effective coupling coefficient as a function of pitch (in micrometers or μm) showing the simulated effective coupling coefficients (k²_{eff}) of coupled bulk acoustic resonators with different thicknesses of dielectric (aluminum oxide Al₂O₃) filling according to various embodiments and of a coupled bulk acoustic resonator with no dielectric filling. FIG. 7C is a plot of frequency (in gigahertz or GHz) as a function of electrode width (elecwid, in micrometers or μm) showing the simulated resonant frequencies of coupled bulk acoustic resonators with different thicknesses of dielectric (aluminum oxide Al₂O₃) filling according to various embodiments and of a coupled bulk acoustic resonator with no dielectric filling. FIG. 7D is a plot of effective coupling coefficient as a function of electrode width (elecwid, in micrometers or μm) showing the simulated effective coupling coefficient of coupled bulk acoustic resonators with different thicknesses of dielectric (aluminum oxide Al₂O₃) filling according to various embodiments and of a coupled bulk acoustic resonator with no dielectric filling.

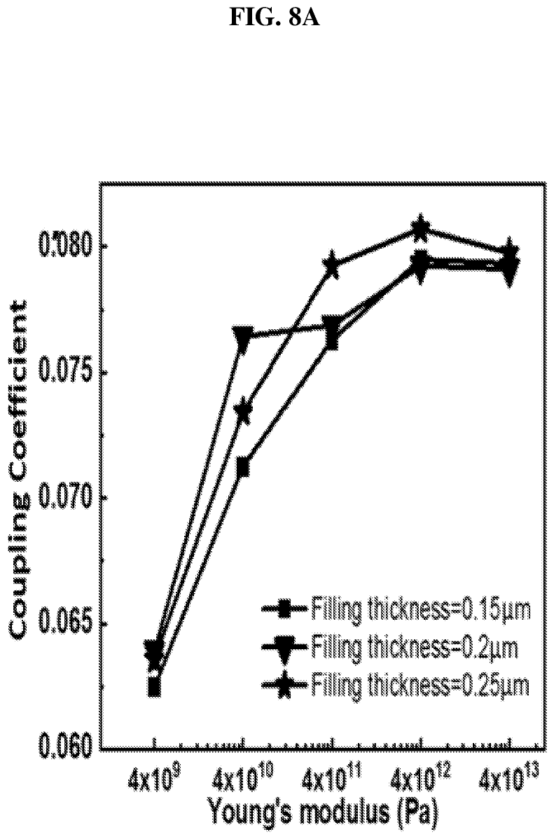

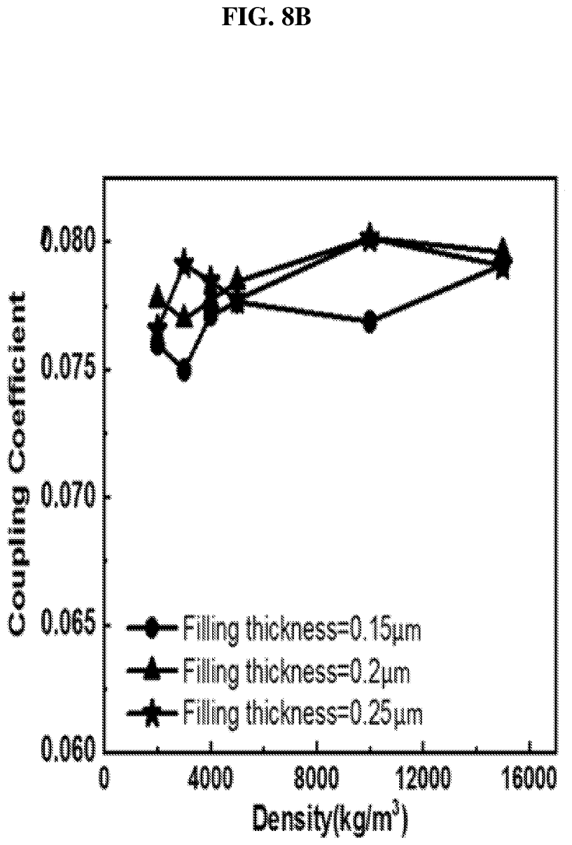

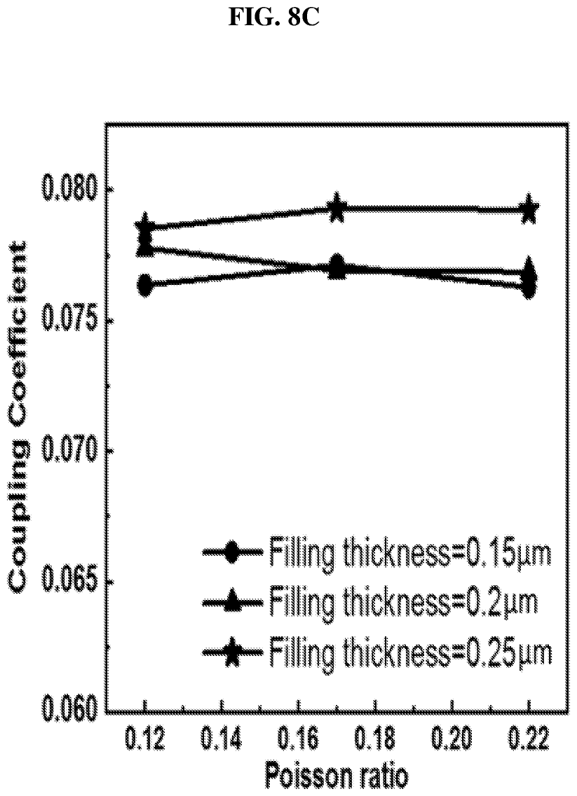

In order to find out the effect of the material property of the filling material, the Young's modulus, density and Poisson ratio of the dielectric may also be swept in the simulation. The simulation results are depicted in FIGS. 8A-C.

FIG. 8A is a plot of effective coupling coefficient as a function of Young's modulus (in Pascals or Pa) highlighting the dependence of the effective coupling coefficient (k²_{eff}) on the Young's modulus of dielectric filling in coupled bulk acoustic resonators with different thicknesses of the dielectric filling according to various embodiments. FIG. 8B is a plot of effective coupling coefficient as a function of density (in kilograms per cubic meters or kg/m³) highlighting the dependence of the effective coupling coefficient (k²_{eff}) on the density of dielectric filling in coupled bulk acoustic resonators with different thicknesses of the dielectric filling according to various embodiments. FIG. 8C is a plot of effective coupling coefficient as a function of Poisson ratio highlighting the dependence of the effective coupling coefficient (k²_{eff}) on the Poisson ratio of dielectric filling in coupled bulk acoustic resonators with different thicknesses of the dielectric filling according to various embodiments.

As shown in FIGS. 8A-C, among the three key mechanical vibration parameters, the most influential parameter is the Young's modulus of the filling material, while the density and Poisson ratio have much less impact on the k²_{eff}. More specifically, increase in the thickness of the filling material with Young's modulus under 4×10¹⁰ may diminish the k²_{eff} of CBAR instead of improving it. Various embodiments may include dielectric structures including a dielectric material with a Young's modulus of more than 4×10¹⁰ Pa. Common dielectric materials which can be used for k²_{eff} improvement purpose may include but may not be limited to Al₂O₃, Si₃N₄, SiO₂, ZnO, AN, HfO₂, TiO₂, RuO₂, HfSiO₄, ZrO₂, ZrSiO₄, Ta₂O₅, HfZrO₄, and so on.

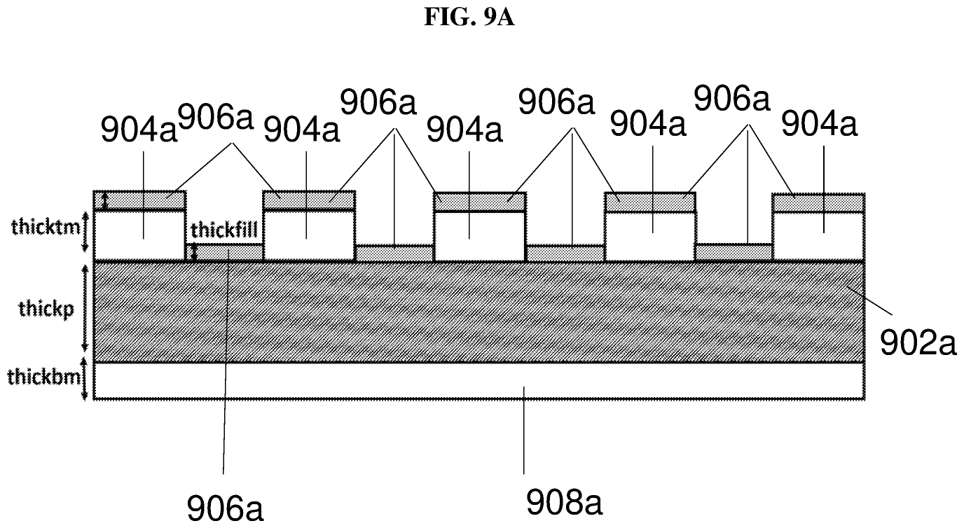

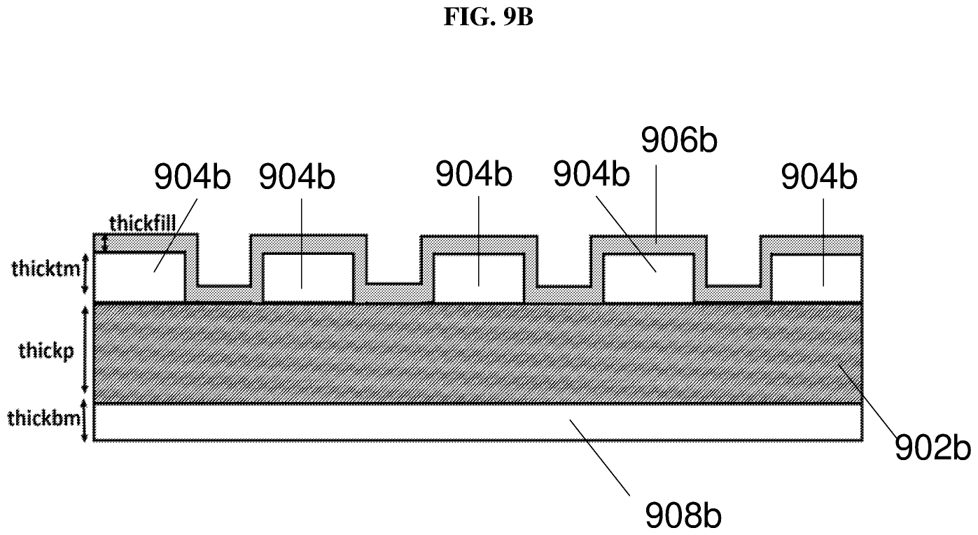

The choice of deposition methods for the dielectric material may result in different profiles. FIG. 9A shows a schematic of a cross-sectional view of a coupled bulk acoustic resonator (CBAR) with dielectric structures 906a on the top surfaces of the electrode structures 904a and on the piezoelectric layer 902a not covered by the electrode structures 904a, but not on the sidewalls of the electrode structures 904a according to various embodiments. The CBAR may also include an electrode 908a at an opposing surface of the piezoelectric layer 902a.

FIG. 9B shows a schematic of a cross-sectional view of a coupled bulk acoustic resonator (CBAR) in which the dielectric structure 906b extends from between the pair of neighboring electrode structures 904b (i.e. on the piezoelectric layer 902b not covered by the electrode structures 904b) along the opposite facing sidewalls to over the electrode structures 904b according to various embodiments. The CBAR may also include an electrode 908b at an opposing surface of the piezoelectric layer 902b.

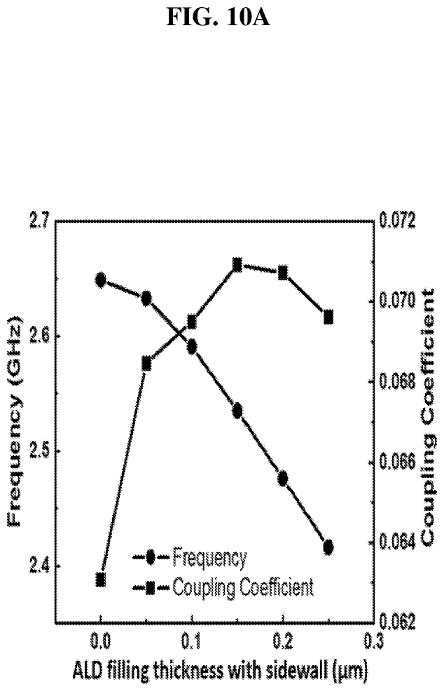

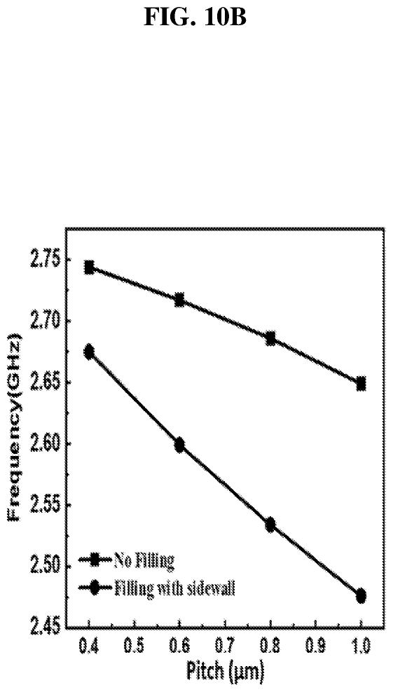

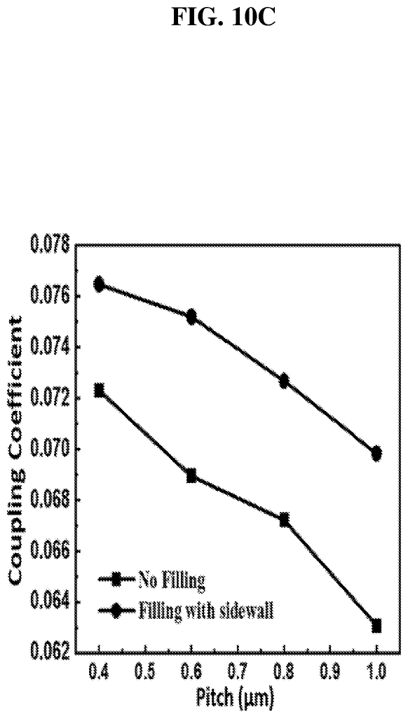

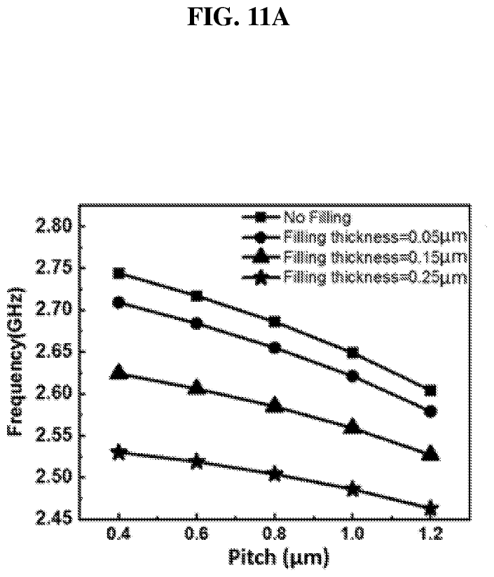

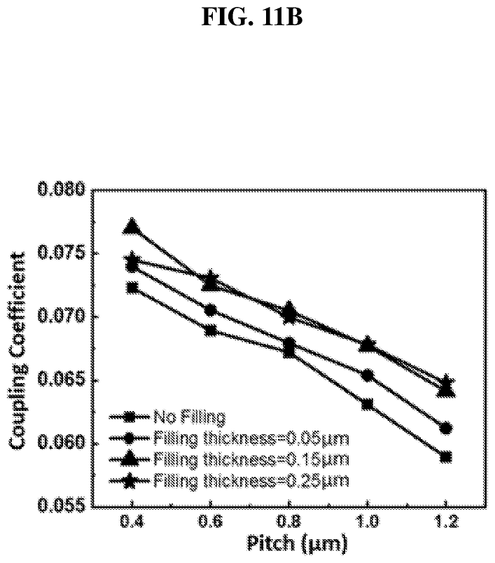

The impact of depositing the dielectric material or fillings on the sidewalls is explored and the simulation results are shown in FIGS. 10A-C and FIGS. 11A-B.

FIG. 10A is a plot of frequency (in gigahertz or GHz)/effective coupling coefficient as a function of filling thickness (in micrometers or μm) showing the performance of a coupled bulk acoustic resonator (CBAR) as illustrated by FIG. 9.B according to various embodiments. The dielectric filling may be deposited by atomic layer deposition (ALD). FIG. 10B is a plot of frequency (in gigahertz or GHz) as a function of pitch (in micrometers or μm) comparing a coupled bulk acoustic resonator (CBAR) with dielectric filling on the side walls according to various embodiments with a coupled bulk acoustic resonator (CBAR) with no dielectric filling. FIG. 10C is a plot of effective coupling coefficient as a function of pitch (in micrometers or μm) comparing a coupled bulk acoustic resonator (CBAR) with dielectric filling on the side walls according to various embodiments with a coupled bulk acoustic resonator (CBAR) with no dielectric filling.

FIG. 11A is a plot of frequency (in gigahertz or GHz) as a function of pitch (in micrometers or μm) showing the simulated resonant frequencies of coupled bulk acoustic resonators (CBAR) with different thicknesses of dielectric fillings on the top electrode (i.e. without dielectric filling along the side walls) according to various embodiments as well as a coupled bulk acoustic resonator (CBAR) without any dielectric filling. FIG. 11B is a plot of effective coupling coefficient as a function of pitch (in micrometers or μm) showing the simulated effective coupling coefficients of coupled bulk acoustic resonators (CBAR) with different thicknesses of dielectric fillings on the top electrode (i.e. without dielectric filling along the side walls) according to various embodiments as well as a coupled bulk acoustic resonator (CBAR) without any dielectric filling.

As shown in the simulated results, the addition of the dielectric material on top electrode sidewalls may not reduce the improvement of the effective coupling coefficient k²_{eff}. In the simulations, the periodic arrangement includes one electrode and one neighboring space.

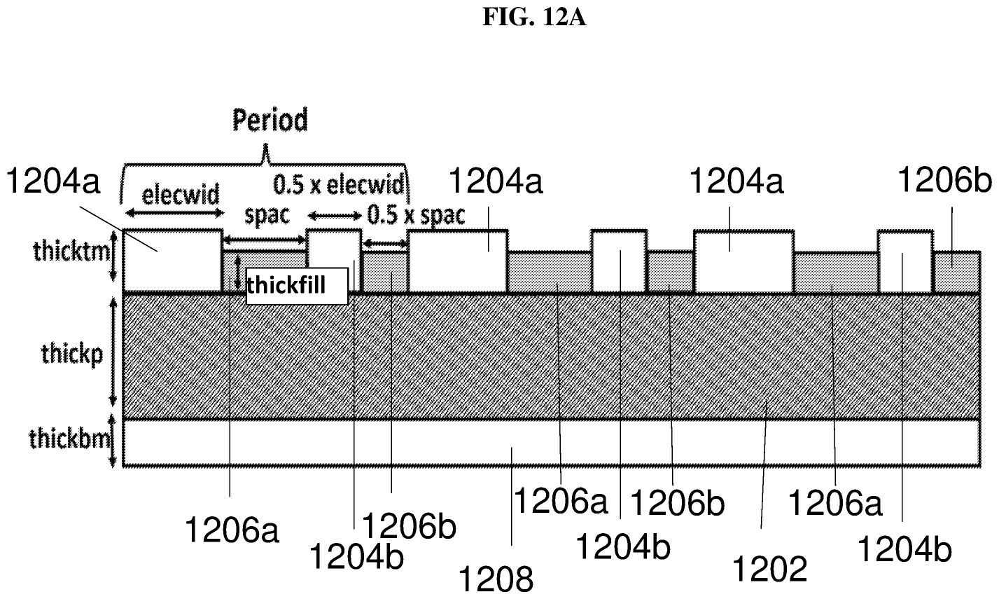

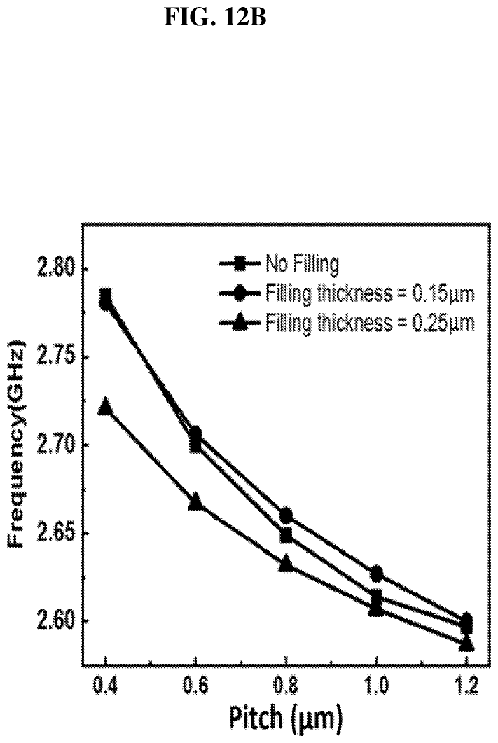

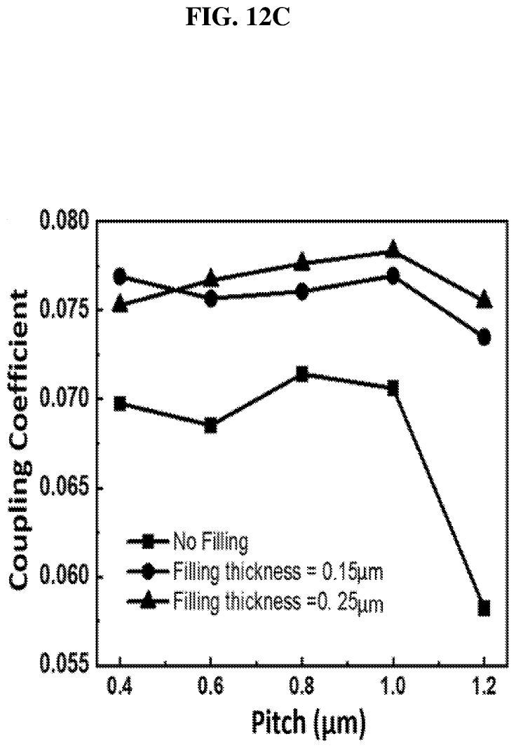

The inclusion of dielectric structures to improve effective coupling coefficient k²_{eff} may be also applicable to resonators with different electrode patterns. In various embodiments, the CBAR may include two types of electrode structures and two types of spaces. FIG. 12A is a schematic showing a cross-sectional view of a coupled bulk acoustic resonator (CBAR) according to various embodiments. The acoustic resonator may include a piezoelectric layer 1202, and a first electrode including electrode structures 1204a, 1204b in contact with a first surface of the piezoelectric layer 1202. The acoustic resonator may also include dielectric structures 1206a, 1206b in contact with the first surface of the piezoelectric layer 1202. The acoustic resonator may further include a second electrode 1208 in contact with a second surface of the piezoelectric layer 1202 opposite the first surface. The electrode structure 1204a may have a width (elewid), while the electrode structure 1204b may have a width 0.5× elewid, i.e. half of the width of electrode structure 1204a. Further, the dielectric structure 1206a may have a width spac, while the dielectric structure 1206b may have a width 0.5× spac. A dielectric structure 1206a may adjoin an electrode structure 1204a on a first side and an electrode structure 1204b on a second side opposite the first side. Further, a dielectric structure 1206b may adjoin an electrode structure 1204b on a first side and an electrode structure 1204a on a second side opposite the first side. In other words, the periodic top electrode may be arranged as full finger/full space/half finger/half space. The simulation results indicate that for the resonator shown in FIG. 12A, filling the spaces with dielectric material may still improve the effective coupling coefficient k²_{eff} effectively. FIG. 12B is a plot of frequency (in gigahertz or GHz) as a function of pitch (in micrometers or μm) showing the resonant frequencies of the coupled bulk acoustic resonator (CBAR) shown in FIG. 12A with different dielectric thicknesses according to various embodiments as well as a coupled bulk acoustic resonator (CBAR) with no dielectric filling. FIG. 12C is a plot of effective coupling coefficient as a function of pitch (in micrometers or μm) showing the effective coupling coefficient of the coupled bulk acoustic resonator (CBAR) shown in FIG. 12A with different dielectric thicknesses according to various embodiments as well as a coupled bulk acoustic resonator (CBAR) with no dielectric filling.

Theoretically, the inclusion of dielectric structures may have an effect on a CBAR with any top electrode pattern, periodic or non-periodic. In practical resonator designs, designers may prefer simple periodic pattern to avoid the generation of spurious modes.

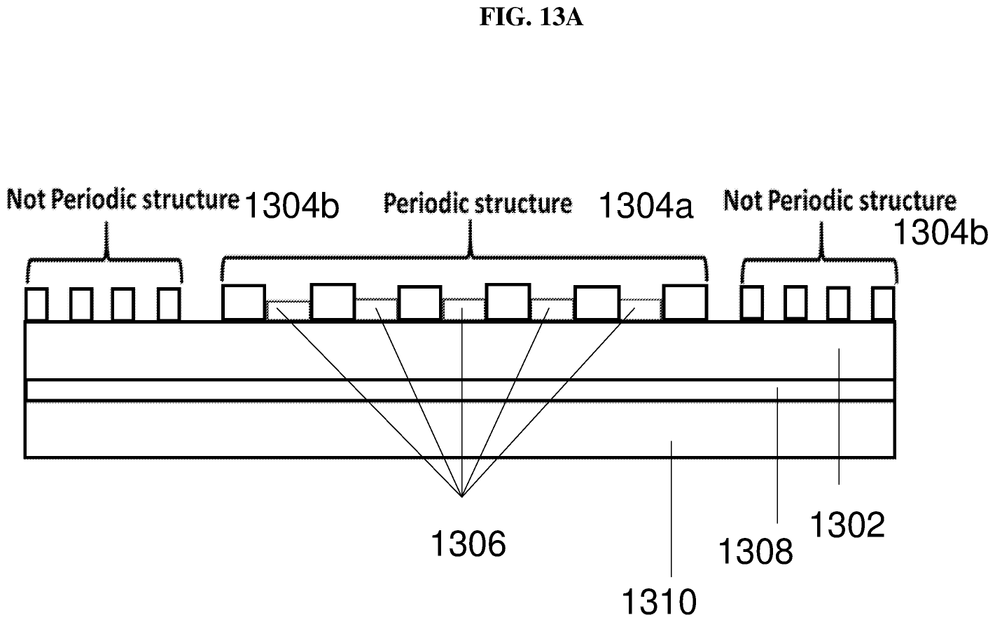

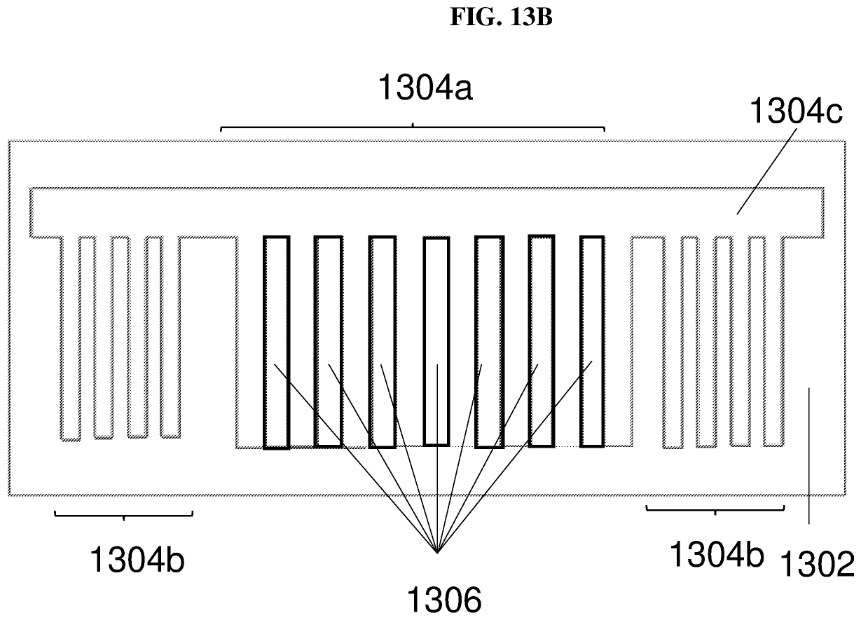

FIG. 13A is a schematic showing a cross-sectional view of a coupled bulk acoustic resonator (CBAR) according to various embodiments. FIG. 13B is a schematic showing a top view of the coupled bulk acoustic resonator (CBAR) shown in FIG. 13A according to various embodiments. The acoustic resonator may include a piezoelectric layer 1302. The acoustic resonator may also include a first electrode including a periodic arrangement of electrode structures 1304a and a non-periodic arrangement of electrode structures 1304b in contact with a first surface of the piezoelectric layer 1302. The electrode structures 1304a, 1304b may extend from an electrode bar 1304c of the first electrode. The acoustic resonator may further include a plurality of dielectric structures 1306 in contact with the first surface of the piezoelectric layer 1302. The acoustic resonator may additionally include a second electrode 1308 in contact with a second surface of the piezoelectric layer 1302 opposite the first surface. A dielectric structure of the plurality of dielectric structures 1306 may be in contact with a pair of neighboring electrode structures of the periodic arrangement of electrode structures 1302a. The second electrode 1308 may be on a substrate 1310.

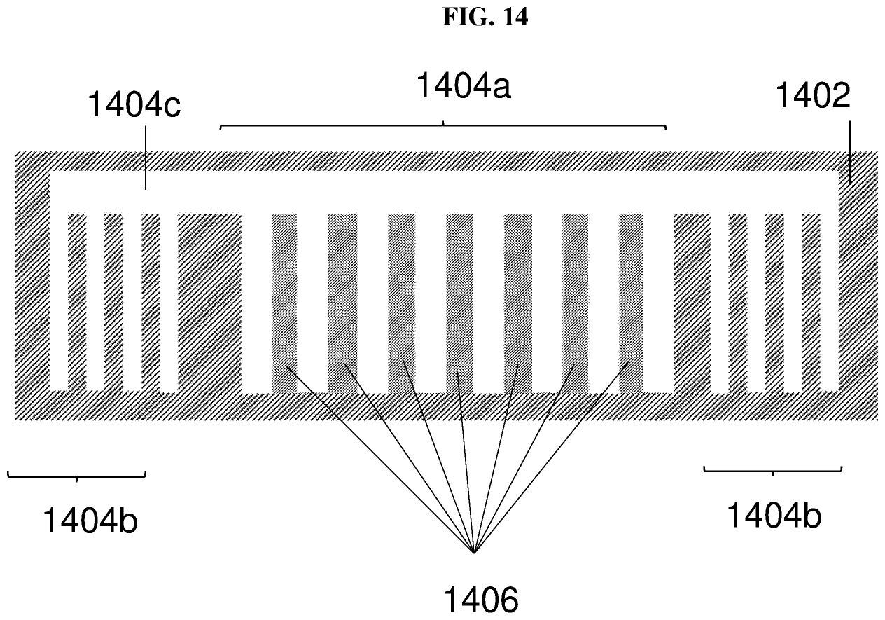

FIG. 14 is a schematic showing a top view of a coupled bulk acoustic resonator (CBAR) according to various embodiments. The resonator may include a piezoelectric layer 1402, a first arrangement of electrode structures 1404a, a second arrangement of electrode structures 1404b, an electrode bar 1404c connecting the electrode structures 1404a, 1404b, and a plurality of dielectric structures 1406. The resonator shown in FIG. 14 may be similar to the resonator shown in FIG. 13B, but with ends of the electrode bar 1404c joining an electrode structure 1404b in an “L” shape. The resonator may also include a second electrode in contact with an opposing surface of the piezoelectric layer 1402.

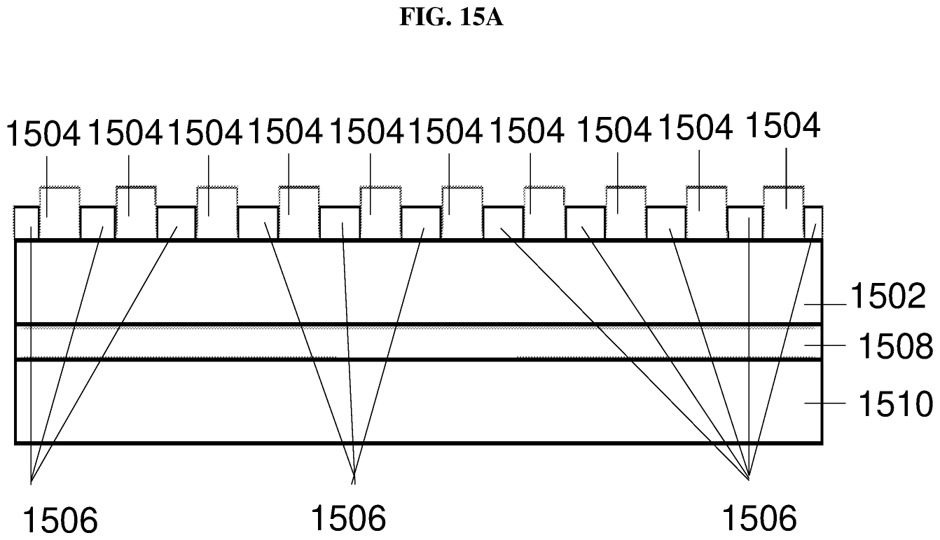

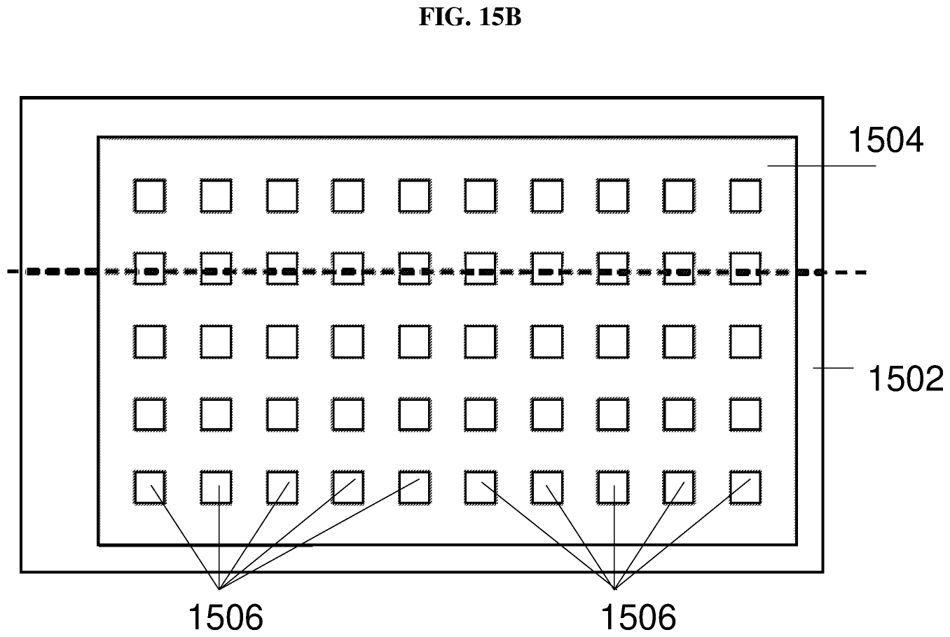

FIG. 15A is a schematic showing a cross-sectional view of a coupled bulk acoustic resonator (CBAR) according to various embodiments. FIG. 15B is a schematic showing a top view of the coupled bulk acoustic resonator (CBAR) shown in FIG. 15A according to various embodiments. The acoustic resonator may include a piezoelectric layer 1502. The acoustic resonator may also include a first electrode 1504 which may be a mesh. The acoustic resonator may further include a plurality of dielectric structures 1506 in contact with the first surface of the piezoelectric layer 1502. The plurality of dielectric structures 1506 may be within the square or rectangular cavities defined by the first electrode 1504 and the underlying piezoelectric layer 1502. In order to avoid clutter and to improve clarity, only the bottommost row of dielectric structures 1506 in FIG. 15B has been labelled. The acoustic resonator may additionally include a second electrode 1508 in contact with a second surface of the piezoelectric layer 1502 opposite the first surface. The second electrode 1508 may be on a substrate 1510.

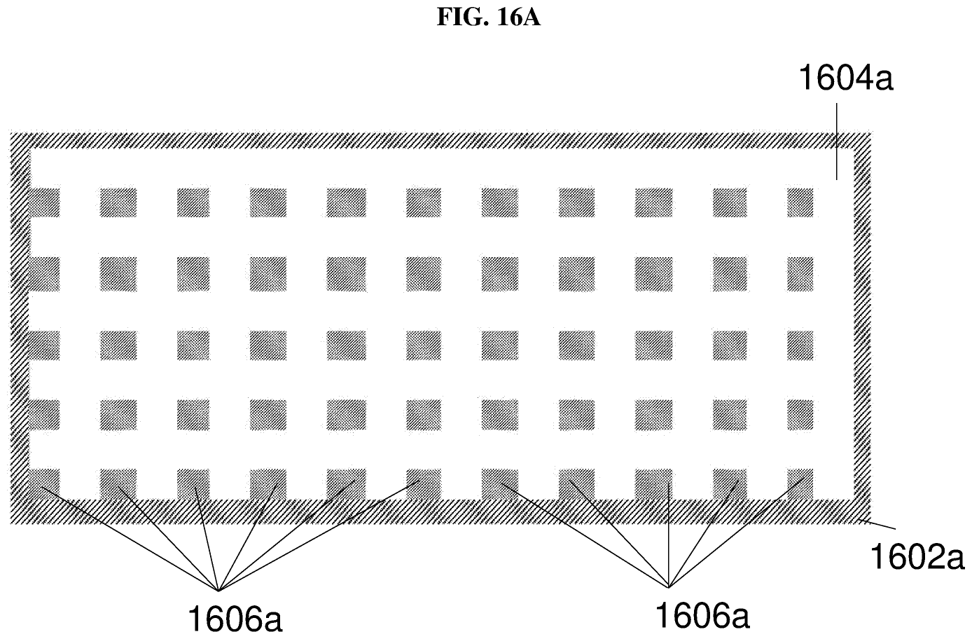

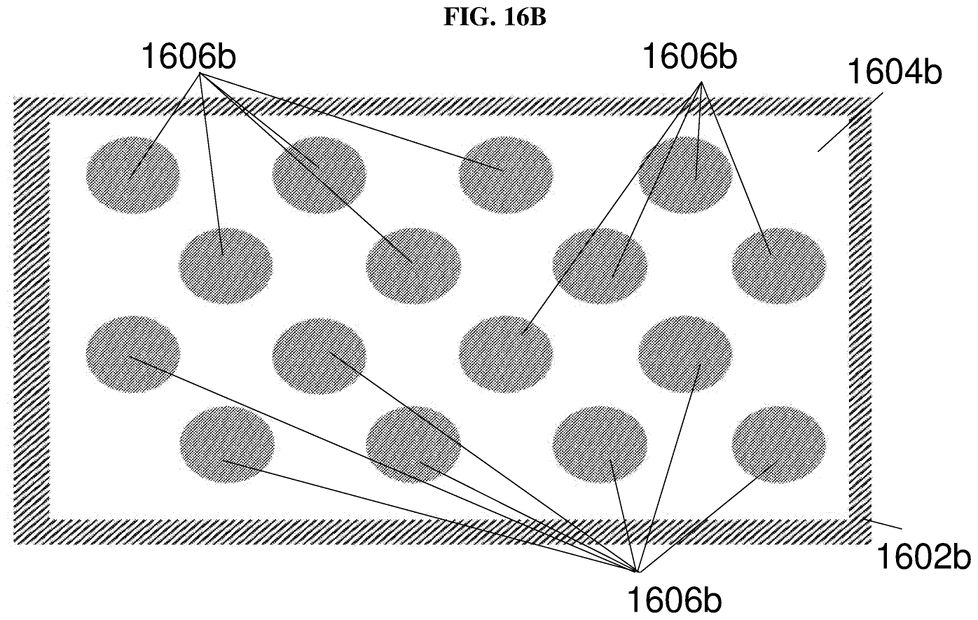

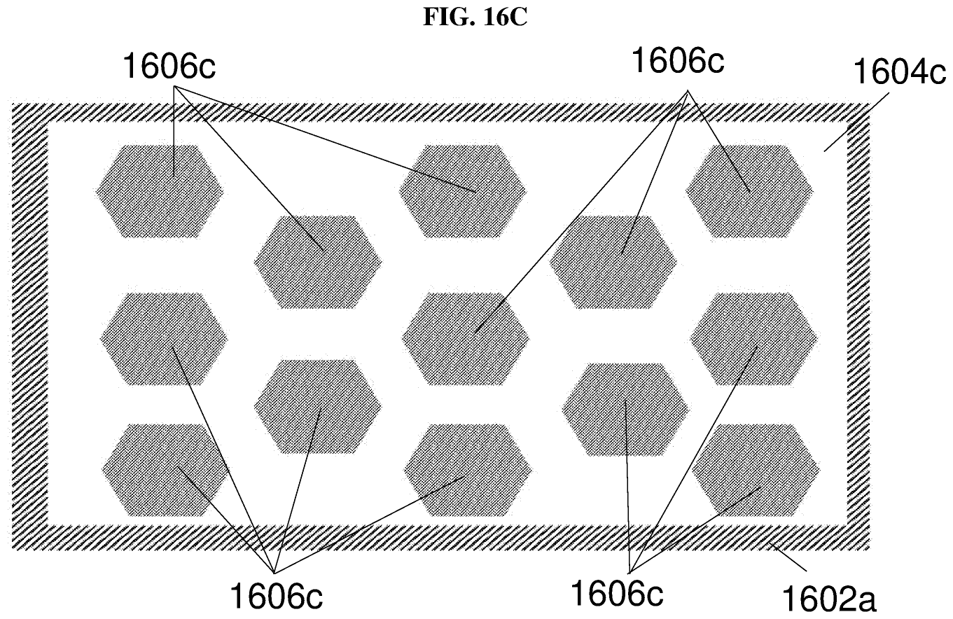

FIG. 16A is a schematic showing a top view of a coupled bulk acoustic resonator (CBAR) according to various embodiments. The resonator shown in FIG. 16A may be similar to the resonator shown in FIG. 15B. The resonator may include a piezoelectric layer 1602a, a first electrode 1604a which may be a mesh, and a plurality of dielectric structures 1606a. The resonator may also include a second electrode in contact with an opposing surface of the piezoelectric layer 1602a. In order to avoid clutter and to improve clarity, only the bottommost row of dielectric structures 1606a has been labelled.

FIG. 16B is a schematic showing a top view of a coupled bulk acoustic resonator (CBAR) according to various other embodiments. The resonator may include a piezoelectric layer 1602b, a first electrode 1604b which may be a mesh, and a plurality of dielectric structures 1606b. The resonator may also include a second electrode in contact with an opposing surface of the piezoelectric layer 1602b. Unlike the resonators shown in FIGS. 15B and 16A, the mesh of the resonator shown in FIG. 16B may define circular cavities.

FIG. 16C is a schematic showing a top view of a coupled bulk acoustic resonator (CBAR) according to various other embodiments. The resonator may include a piezoelectric layer 1602c, a first electrode 1604c which may be a mesh, and a plurality of dielectric structures 1606c. The resonator may also include a second electrode in contact with an opposing surface of the piezoelectric layer 1602c. The mesh of the resonator shown in FIG. 16C may define hexagonal cavities.

Various embodiments may include a first electrode in the form of a mesh. The mesh may define cavities of any suitable shape.

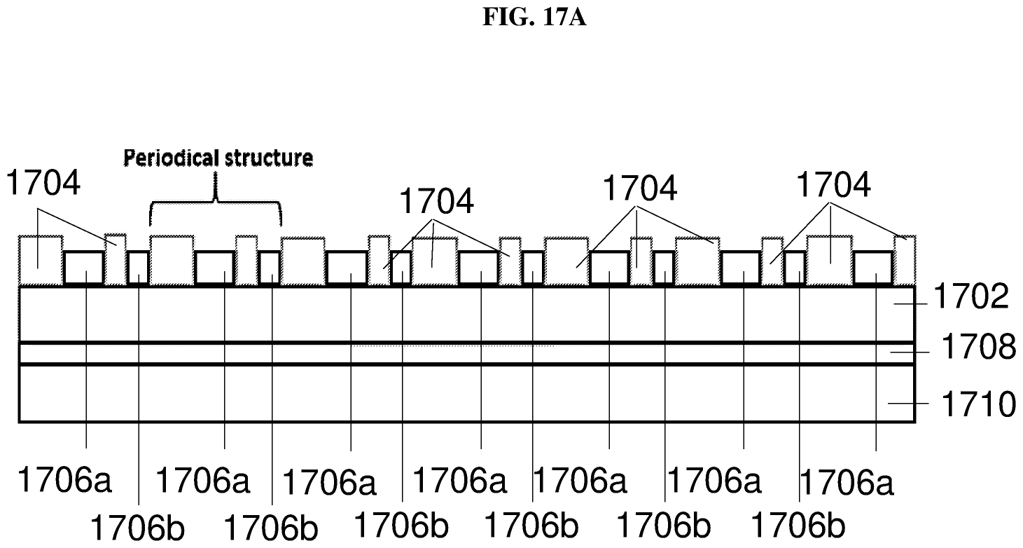

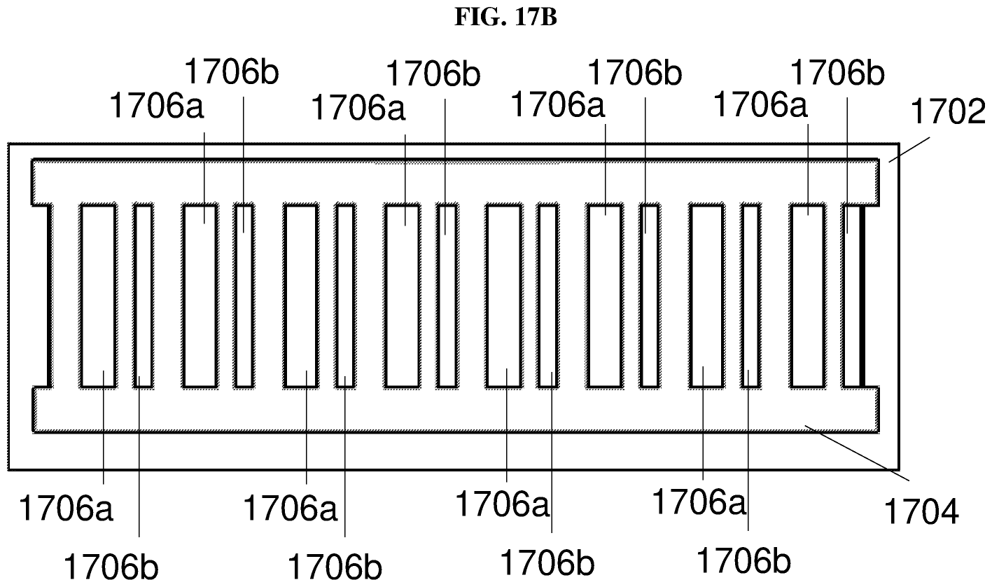

FIG. 17A is a schematic showing a cross-sectional view of a coupled bulk acoustic resonator (CBAR) according to various embodiments. FIG. 17B is a schematic showing a top view of the coupled bulk acoustic resonator (CBAR) shown in FIG. 17A according to various embodiments. The acoustic resonator may be similar to the acoustic resonator shown in FIG. 12A. The acoustic resonator may include a piezoelectric layer 1702. The acoustic resonator may also include a first electrode 1704. The electrode structure may include a first plurality of electrode structures of a first width and a second plurality of electrode structure of a second width different from the first width. The first plurality of structures and the second plurality of electrode structures may be alternately arranged, and may extend between a first electrode bar at a first end and a second electrode bar at a second end. The acoustic resonator may further include a first plurality of dielectric structures 1706a and a second plurality of dielectric structures 1706b in contact with the first surface of the piezoelectric layer 1702. The width of each of the second plurality of dielectric structures 1706b may be different from the width of each of the first plurality of dielectric structures 1706a. The acoustic resonator may additionally include a second electrode 1708 in contact with a second surface of the piezoelectric layer 1702 opposite the first surface. The second electrode 1708 may be on a substrate 1710.

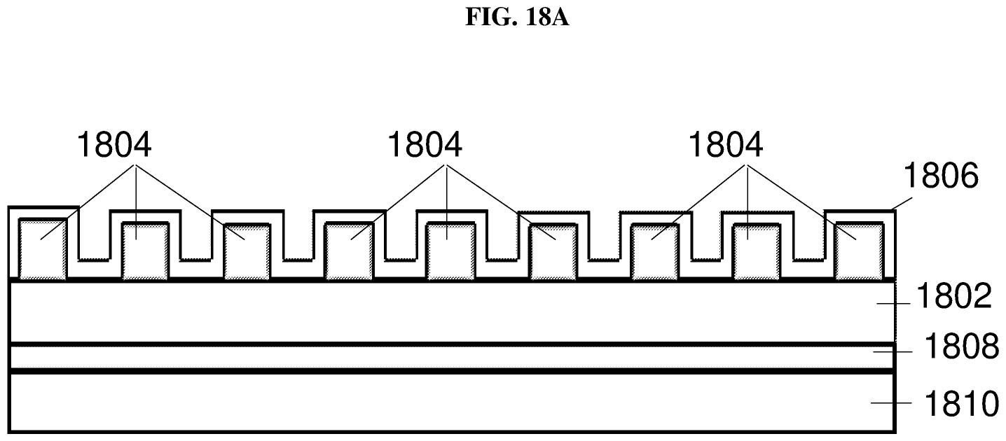

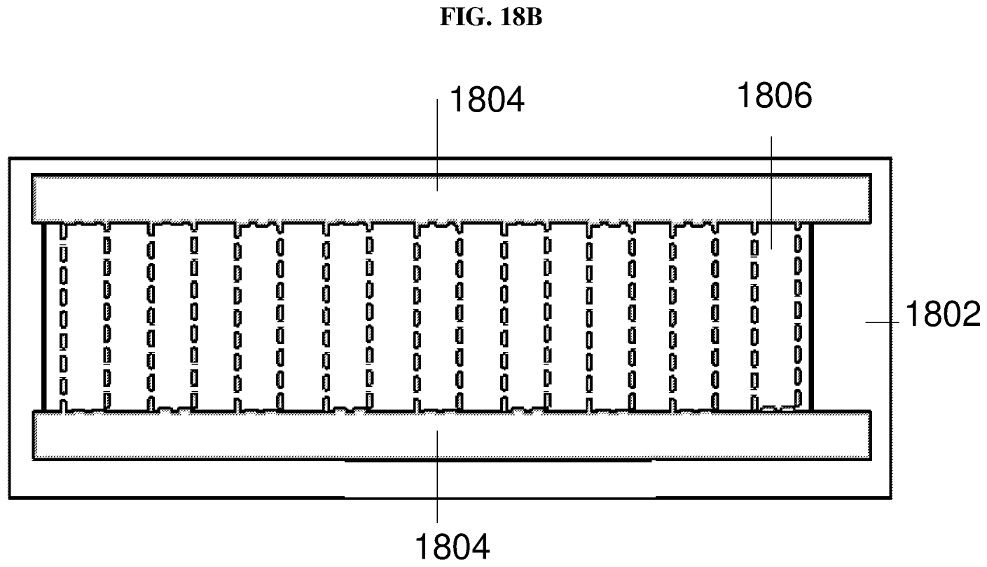

FIG. 18A is a schematic showing a cross-sectional view of a coupled bulk acoustic resonator (CBAR) according to various embodiments. FIG. 18B is a schematic showing a top view of the coupled bulk acoustic resonator (CBAR) shown in FIG. 18A according to various embodiments. The acoustic resonator may be similar to the acoustic resonator shown in FIG. 9B. The acoustic resonator may include a piezoelectric layer 1802. The acoustic resonator may also include a first electrode 1804. As shown in FIG. 18B, the electrode structure may include a plurality of electrode structures extending between a first electrode bar at a first end and a second electrode bar at a second end. The acoustic resonator may further include a plurality of dielectric structures 1806 in contact with the first surface of the piezoelectric layer 1802. The plurality of dielectric structures may extend along the sidewalls and over the first electrode 1804 to contact one another to form a dielectric layer. The acoustic resonator may additionally include a second electrode 1808 in contact with a second surface of the piezoelectric layer 1802 opposite the first surface. The second electrode 1808 may be on a substrate 1810.

By “comprising” it is meant including, but not limited to, whatever follows the word “comprising”. Thus, use of the term “comprising” indicates that the listed elements are required or mandatory, but that other elements are optional and may or may not be present.

By “consisting of” is meant including, and limited to, whatever follows the phrase “consisting of”. Thus, the phrase “consisting of” indicates that the listed elements are required or mandatory, and that no other elements may be present.

The inventions illustratively described herein may suitably be practiced in the absence of any element or elements, limitation or limitations, not specifically disclosed herein. Thus, for example, the terms “comprising”, “including”, “containing”, etc. shall be read expansively and without limitation. Additionally, the terms and expressions employed herein have been used as terms of description and not of limitation, and there is no intention in the use of such terms and expressions of excluding any equivalents of the features shown and described or portions thereof, but it is recognized that various modifications are possible within the scope of the invention claimed. Thus, it should be understood that although the present invention has been specifically disclosed by preferred embodiments and optional features, modification and variation of the inventions embodied therein herein disclosed may be resorted to by those skilled in the art, and that such modifications and variations are considered to be within the scope of this invention.

By “about” in relation to a given numerical value, such as for temperature and period of time, it is meant to include numerical values within 10% of the specified value.

The invention has been described broadly and generically herein. Each of the narrower species and sub-generic groupings falling within the generic disclosure also form part of the invention. This includes the generic description of the invention with a proviso or negative limitation removing any subject matter from the genus, regardless of whether or not the excised material is specifically recited herein.

Other embodiments are within the following claims and non-limiting examples.

1. An acoustic resonator comprising:
a piezoelectric layer;
a first electrode in contact with a first surface of the piezoelectric layer, a plurality of dielectric structures in contact with the first surface of the piezoelectric layer; and
a second electrode in contact with a second surface of the piezoelectric layer opposite the first surface;
wherein the first electrode comprises a plurality of electrode structures; and
wherein a dielectric structure of the plurality of dielectric structures is in contact with a pair of neighboring electrode structures of the plurality of electrode structures.

2. The acoustic resonator according to claim 1,
wherein a pitch between one pair of neighboring electrode structures of the plurality of electrode structures and a pitch between another pair of neighboring electrode structures of the plurality of electrode structures is equal.

3. The acoustic resonator according to claim 1,
wherein a pitch between one pair of neighboring electrode structures of the plurality of electrode structures is not equal to a pitch between another pair of neighboring electrode structures of the plurality of electrode structures.

4. The acoustic resonator according to claim 1,
wherein the first electrode further comprises an electrode bar such that the plurality of electrode structures extends from the electrode bar.

5. The acoustic resonator according to claim 4,
wherein the first electrode further comprises one or more additional electrode bars across the plurality of electrode structures such that the first electrode is a mesh.

6. The acoustic resonator according to claim 1,
wherein the dielectric structure covers opposite facing sidewalls of the pair of the neighboring electrode structures.

7. The acoustic resonator according to claim 6,
wherein the dielectric structure extends from between the pair of neighboring electrode structures along the opposite facing sidewalls to over the pair of neighboring electrode structures.

8. The acoustic resonator according to claim 1,
wherein the plurality of electrode structures has a first thickness; and wherein the plurality of dielectric structures has a second thickness not equal to the first thickness.

9. The acoustic resonator according to claim 1,
wherein the plurality of electrode structures is configured to be applied with a first voltage and the second electrode is configured to be applied with a second voltage different from the first voltage.

10. The acoustic resonator according to claim 1,
wherein the plurality of dielectric structures comprises any one material selected from a group consisting of aluminum oxide (AI2O3), silicon nitride (Si3N4), silicon dioxide (SiO2), zinc oxide (ZnO), aluminum nitride (AIN), scandium aluminum nitride (ScAlN), hafnium oxide (HfO2), titanium oxide (TiO2), ruthenium oxide (RuO2), hafnium silicate (HfSiO4), zirconium oxide (Z1O2), zirconium silicate (ZrSiO4), tantalum oxide (Ta2O5), hafnium zirconium oxide (HfZrO4).

11. A method of forming an acoustic resonator, the method comprising:
forming a first electrode in contact with a first surface of a piezoelectric layer; forming a plurality of dielectric structures in contact with the first surface of the piezoelectric layer; and
forming a second electrode in contact with a second surface of the piezoelectric layer opposite the first surface;
wherein the first electrode comprises a plurality of electrode structures; and wherein a dielectric structure of the plurality of dielectric structures is in contact with a pair of neighboring electrode structures of the plurality of electrode structures.

12. The method according to claim 11,
wherein a pitch between one first pair of neighboring electrode structures of the plurality of electrode structures and a pitch between another pair of neighboring electrode structures of the plurality of electrode structures is equal.

13. The method according to claim 11,
wherein a pitch between one pair of neighboring electrode structures of the plurality of electrode structures is not equal to a pitch between another pair of neighboring electrode structures of the plurality of electrode structures.

14. The method according to claim 11,
wherein the first electrode further comprises an electrode bar such that the plurality of electrode structures extends from the electrode bar.

15. The method according to claim 14,
wherein the first electrode further comprises one or more additional electrode bars across the plurality of electrode structures such that the first electrode is a mesh.

16. The method according to claim 11,
wherein the dielectric structure covers opposite facing sidewalls of the pair of the neighboring electrode structures.

17. The method according to claim 16,
wherein the dielectric structure extends from between the neighboring electrode structures along the opposite facing sidewalls to over the neighboring electrode structures.

18. The method according to claim 11,
wherein the plurality of electrode structures has a first thickness; and wherein the plurality of dielectric structures has a second thickness not equal to the first thickness.

19. The method according to claim 11,
wherein the plurality of electrode structures is configured to be applied with a first voltage and the second electrode is configured to be applied with a second voltage different from the first voltage.

20. The method according to claim 11,
wherein the plurality of dielectric structures comprises any one material selected from a group consisting of consisting of aluminum oxide (AI2O3), silicon nitride (Si3N4), silicon dioxide (SiO2), zinc oxide (ZnO), aluminum nitride (AIN), hafnium oxide (HfO2), titanium oxide (TiO2), ruthenium oxide (RuO2), hafnium silicate (HfSiO₄), zirconium oxide (ZrO2), zirconium silicate (ZrSiO4), tantalum oxide (Ta2O5), hafnium zirconium oxide (HfZrO4).
